(19) United States
(12) Patent Application Publication
(10) Pub. No.: US 2022/0291347 A1
(43) Pub. Date: Sep. 15, 2022

(54) IMAGING ELEMENT AND DISTANCE MEASURING APPARATUS

(71) Applicant: SONY SEMICONDUCTOR SOLUTIONS CORPORATION, Kanagawa (JP)

(72) Inventors: Yusuke OTAKE, Kanagawa (JP); Toshifumi WAKANO, Kanagawa (JP)

(73) Assignee: SONY SEMICONDUCTOR SOLUTIONS CORPORATION, Kanagawa (JP)

(21) Appl. No.: 17/634,315

(22) PCT Filed: Aug. 7, 2020
(86) PCT No.: PCT/JP2020/030311

§ 371 Date: Feb. 10, 2022

(30) Foreign Application Priority Data
Aug. 22, 2019 (JP) 2019-151755

(51) Int. Cl. G01S 7/481; G01S 17/89; H04N 5/3745

(52) U.S. Cl. CPC G01S 7/4816; G01S 17/89; H04N 5/37452; H01L 27/14614

(57) ABSTRACT

An imaging element includes a photoelectric converting section configured to perform photoelectric conversion, a plurality of charge storage sections configured to store charge obtained by the photoelectric converting section, and a plurality of transfer sections configured to transfer the charge from the photoelectric converting section to each of the plurality of charge storage sections. Each of the charge storage sections is provided between a first gate of a transistor included in a corresponding one of the transfer sections and a second gate provided at a position parallel to the first gate.

### TECHNICAL FIELD

The present technology relates to an imaging element and a distance measuring apparatus, and for example, to an imaging element suitably used for a distance measuring apparatus, and the distance measuring apparatus.

### CROSS REFERENCE TO RELATED APPLICATIONS

This application claims the benefit of Japanese Priority Patent Application JP 2019-151755 filed Aug. 22, 2019, the entire contents of which are incorporated herein by reference.

### BACKGROUND ART

In recent years, advanced semiconductor technologies have increasingly miniaturized distance measuring modules measuring a distance to an object. Thus, for example, mounting of a distance measuring module in what is called mobile terminals such as smartphones has been achieved, the mobile terminals corresponding to small information processing apparatuses with a communication function.

In general, a distance measuring method for distance measuring modules includes two types: a TOF (Time of Flight) method and a Structured Light method. In the ToF method, light is radiated toward an object, and light reflected by a surface of the object is detected. The time of flight of the light is measured, and the distance to the object is computed on the basis of the measured value. In the Structured Light method, pattern light is radiated toward the object, and distortion of a pattern on the surface of the object is imaged. On the basis of the resultant image, the distance to the object is computed.

A semiconductor detecting element is known that measures the distance to a target object using the ToF method. In the semiconductor detecting element based on the ToF method, light is radiated from a light source and reflected by the target object, and the reflected light is photo-electrically converted by a photodiode. Signal charge generated by the photoelectric conversion is distributed to two FDs (Floating Diffusions) by a pair of gate electrodes alternately driven (see, for example, PTL 1).

### CITATION LIST

### Patent Literature

PTL 1: Japanese Patent Laid-Open No. 2009-8537

### SUMMARY OF INVENTION

### Technical Problem

In a case of the semiconductor detecting element configured such that the signal charge generated by photoelectric conversion is distributed to the two FDs by the pair of gate electrodes alternately driven, the signal amounts of the respective two FDs may need to be read out, and a difference between the signal amounts may need to be accurately read out. In a case where the two FDs have different capacitances, the difference in signal amount between the two FDs may fail to be accurately read out.

Accordingly, the semiconductor detecting element desirably has a structure in which the two FDs have an equal capacitance.

In view of such circumstances, it is desirable to provide a structure in which a plurality of FDs has an equal capacitance.

### Solution to Problem

A first imaging element according to an embodiment of the present technology includes a photoelectric converting section configured to perform photoelectric conversion, a plurality of charge storage sections configured to store charge obtained by the photoelectric converting section, and a plurality of transfer sections configured to transfer the charge from the photoelectric converting section to each of the plurality of charge storage sections. Each of the charge storage sections is provided between a first gate of a transistor included in a corresponding one of the transfer sections and a second gate provided at a position parallel to the first gate.

A second imaging element according to an embodiment of the present technology includes a photoelectric converting section configured to perform photoelectric conversion, a plurality of charge storage sections configured to store charge obtained by the photoelectric converting section, a plurality of transfer sections configured to transfer the charge from the photoelectric converting section to each of the plurality of charge storage sections, and a trench provided parallel to a gate of a transistor included in a corresponding one of the transfer sections. Each of the charge storage sections is provided between the gate and the trench.

A distance measuring apparatus according to an embodiment of the present technology includes a light emitting section configured to emit irradiation light, a light receiving section configured to receive reflected light resulting from reflection of the irradiation light at a target object, and a computation section configured to compute a distance to the target object on the basis of a period of time from emission of the irradiation light until reception of the reflected light. An imaging element disposed in the light receiving section includes a photoelectric converting section configured to perform photoelectric conversion, a plurality of charge storage sections configured to store charge obtained by the photoelectric converting section, and a plurality of transfer sections configured to transfer the charge from the photoelectric converting section to each of the plurality of charge storage sections. Each of the charge storage sections is provided between a first gate of a transistor included in a corresponding one of the transfer sections and a second gate provided at a position parallel to the first gate.

The first imaging element according to the embodiment of the present technology includes the photoelectric converting section configured to perform photoelectric conversion, the plurality of charge storage sections configured to store charge obtained by the photoelectric converting section, and the plurality of transfer sections configured to transfer the charge from the photoelectric converting section to each of the plurality of charge storage sections. Each of the charge storage sections is provided between the first gate of the transistor included in the corresponding one of the transfer sections and the second gate provided at the position parallel to the first gate.

The second imaging element according to the embodiment of the present technology includes the photoelectric converting section configured to perform photoelectric conversion, the plurality of charge storage sections configured to store charge obtained by the photoelectric converting section, the plurality of transfer sections configured to transfer the charge from the photoelectric converting section to each of the plurality of charge storage sections, and the trench provided parallel to the gate of the transistor included in the corresponding one of the transfer sections. Each of the charge storage sections is provided between the gate and the trench.

The distance measuring apparatus according to the embodiment of the present technology includes the light emitting section configured to emit irradiation light, the light receiving section configured to receive reflected light resulting from reflection of the irradiation light at the target object, and the computation section configured to compute the distance to the target object on the basis of the period of time from emission of the irradiation light until reception of the reflected light. The imaging element disposed in the light receiving section includes the photoelectric converting section configured to perform photoelectric conversion, the plurality of charge storage sections configured to store charge obtained by the photoelectric converting section, and the plurality of transfer sections configured to transfer the charge from the photoelectric converting section to each of the plurality of charge storage sections. Each of the charge storage sections is provided between the first gate of the transistor included in the corresponding one of the transfer sections and the second gate provided at the position parallel to the first gate.

### BRIEF DESCRIPTION OF DRAWINGS

FIG. 1 is a diagram depicting a configuration of an embodiment of a distance measuring apparatus to which the present technology is applied.

FIG. 2 is a diagram depicting a configuration example of a light receiving section.

FIG. 3 is a diagram depicting a configuration example of a pixel.

FIG. 4 is a diagram illustrating distribution of charge in the pixel.

FIG. 5 is a diagram illustrating light emission in the past.

FIG. 6 is a diagram illustrating another readout method.

FIG. 7 is a diagram illustrating occurrence of a difference in capacitance between FDs.

FIG. 8 is a plan view depicting a configuration of a pixel according to a first embodiment.

FIG. 9 is a diagram illustrating a case of no difference in capacitance between the FDs.

FIG. 10 is a plan view depicting another configuration of the pixel according to the first embodiment.

FIG. 11 is a plan view depicting a configuration of a pixel according to a second embodiment.

FIG. 12 is a plan view depicting another configuration of the pixel according to the second embodiment.

FIG. 13 is a plan view depicting a configuration of a pixel according to a third embodiment.

FIG. 14 is a circuit diagram depicting the configuration of the pixel according to the third embodiment.

FIG. 15 is a plan view depicting another configuration of the pixel according to the third embodiment.

FIG. 16 is a diagram depicting a configuration example of pixels disposed in a vertical direction.

FIG. 17 is a plan view depicting a configuration of a pixel according to a fourth embodiment.

FIG. 18 is a diagram depicting an example of line-symmetrically disposed transistors.

FIG. 19 is a diagram depicting an example of point-symmetrically disposed transistors.

FIG. 20 is a plan view depicting a configuration of a pixel according to a fifth embodiment.

FIG. 21 is a plan view depicting another configuration of the pixel according to the fifth embodiment.

FIG. 22 is a plan view depicting a configuration of a pixel according to a sixth embodiment.

FIG. 23 is a cross-sectional view depicting the configuration of the pixel according to the sixth embodiment.

FIG. 24 is a diagram illustrating a vertical transistor.

FIG. 25 is a diagram illustrating occurrence of a difference in capacitance between the FDs.

FIG. 26 is a plan view depicting a configuration of a pixel according to a seventh embodiment.

FIG. 27 is a cross-sectional view depicting the configuration of the pixel according to the seventh embodiment.

FIG. 28 is a view depicting an example of a schematic configuration of an endoscopic surgery system.

FIG. 29 is a block diagram depicting an example of a functional configuration of a camera head and a camera control unit (CCU).

FIG. 30 is a block diagram depicting an example of schematic configuration of a vehicle control system.

FIG. 31 is a diagram of assistance in explaining an example of installation positions of an outside-vehicle information detecting section and an imaging section.

### DESCRIPTION OF EMBODIMENTS

Embodiments of the present technology (hereinafter referred to as the embodiments) will be described below.

The present technology according to an embodiment of the present disclosure can be applied to a light receiving element included in a distance measuring system performing distance measurement using, for example, an indirect TOF method, and an imaging apparatus including such a light receiving element.

For example, the distance measuring system can be applied to, for example, a vehicle-mounted system mounted in a vehicle to measure a distance to a target object outside the vehicle, and a system for gesture recognition measuring a distance to a target object such as the hand of a user to recognize a gesture of the user on the basis of a result of the measurement. In this case, the result of the gesture recognition can be used, for example, for operation of a car navigation system.

<Configuration Example of Distance Measuring Apparatus>

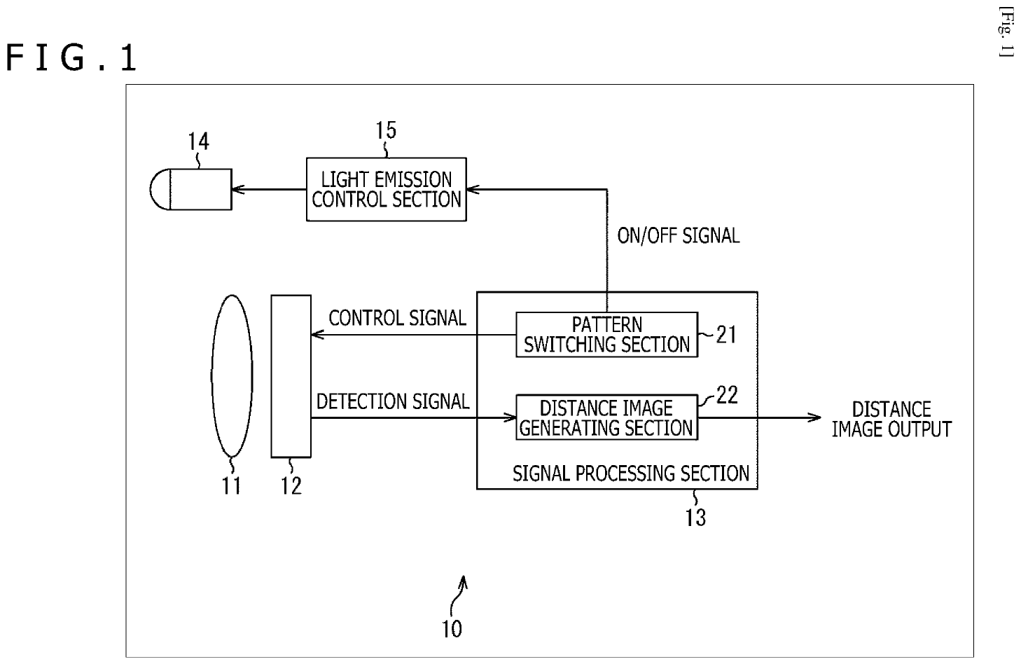

FIG. 1 depicts a configuration example of an embodiment of a distance measuring apparatus to which the present technology is applied.

The distance measuring apparatus 10 includes a lens 11, a light receiving section 12, a signal processing section 13, a light emitting section 14, and a light emission control section 15. The signal processing section 13 includes a pattern switching section 21 and a distance image generating section 22. The distance measuring apparatus 10 in FIG. 1 radiates light to an object and receives light (reflected light) resulting from reflection of the radiated light (irradiation light) by the object, to measure a distance to the object.

A light emitting system of the distance measuring apparatus 10 includes the light emitting section 14 and the light emission control section 15. In the light emitting system, the light emission control section 15 causes, under the control of the signal processing section 13, the light emitting section 14 to radiate infrared light (IR). An IR bandpass filter may be provided between the lens 11 and the light receiving section 12, and the light emitting section 14 may emit infrared light corresponding to a transmitted wavelength band of the IR bandpass filter.

The light emitting section 14 may be disposed inside a housing of the distance measuring apparatus 10 or outside the housing of the distance measuring apparatus 10. The light emission control section 15 causes the light emitting section 14 to emit light in a predetermined pattern. The pattern is set by the pattern switching section 21 and configured to be switched at a predetermined timing.

The pattern switching section 21 can be provided and configured to, for example, switch the light emission pattern while preventing the light emission pattern from overlapping a pattern of another distance measuring apparatus 10. Additionally, the pattern switching section 21 as described above can be omitted.

The signal processing section 13 functions as a computation section computing a distance from the distance measuring apparatus 10 to an object, for example, on the basis of an image signal supplied from the light receiving section 12. In a case where the computed distance is output as an image, the distance image generating section 22 of the signal processing section 13 generates and outputs a distance image representing the distance to the object for each of pixels.

<Configuration of Imaging Element>

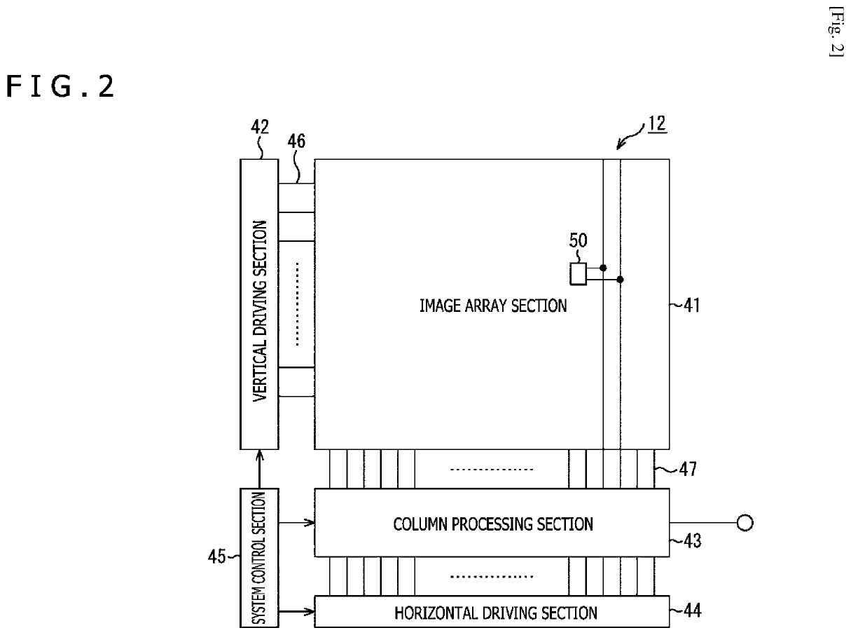

FIG. 2 is a block diagram depicting a configuration example of the light receiving section 12. The light receiving section 12 can include a CMOS (Complementary Metal Oxide Semiconductor) image sensor.

The light receiving section 12 includes a pixel array section 41, a vertical driving section 42, a column processing section 43, a horizontal driving section 44, and a system control section 45. The pixel array section 41, the vertical driving section 42, the column processing section 43, the horizontal driving section 44, and the system control section 45 are provided on a semiconductor substrate (chip) not illustrated.

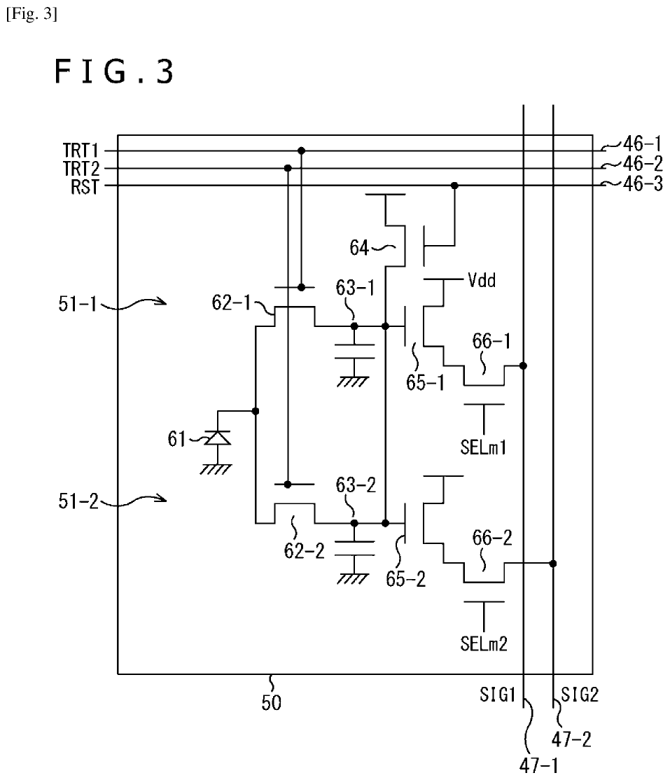

The pixel array section 41 includes unit pixels (for example, a pixel 50 in FIG. 3) two-dimensionally arranged in a matrix and each including a photoelectric converting element generating photocharge the amount of which corresponds to the amount of incident light, the photoelectric converting element internally storing the photocharge. Note that the photocharge the amount of which corresponds to the amount of incident light may hereinafter simply be described as the “charge” and that the unit pixel may hereinafter simply be described as the “pixel.”

The pixel array section 41 further includes, with respect to the matrix-like pixel array, pixel driving lines 46 for the respective rows along a lateral direction (array direction of the pixels in the pixel rows) in FIG. 2 and vertical signal lines 47 for respective columns along an up-down direction (array direction of the pixels in the pixel columns) in FIG. 2. One end of each of the pixel driving lines 46 is connected to a corresponding one of output ends of the vertical driving section 42 for the respective rows.

The vertical driving section 42 is a pixel driving section including a shift register, an address decoder, or the like, and simultaneously driving all the pixels of the pixel array section 41 or driving the pixels in units of rows or the like. A pixel signal output from each of the unit pixels in the pixel row selected and scanned by the vertical driving section 42 is supplied to the column processing section 43 through the corresponding one of the vertical signal lines 47. The column processing section 43 executes, for each pixel column of the pixel array section 41, predetermined signal processing on the pixel signal output through the vertical signal line 47 from the corresponding unit pixel in the selected row, and temporarily holds the pixel signal resulting from the signal processing.

Specifically, the column processing section 43 executes, as signal processing, at least denoising processing, for example, CDS (Correlated Double Sampling) processing. The correlated double sampling by the column processing section 43 eliminates reset noise and fixed pattern noise specific to the pixels, such as variation in threshold among amplifying transistors. Note that, besides the denoising processing, the column processing section 43 can be provided with, for example, an AD (Analog-Digital) converting function to output a signal level with a digital signal.

The horizontal driving section 44 includes a shift register, an address decoder, or the like, and sequentially selects unit circuits corresponding to the pixel columns in the column processing section 43. The selection and scanning by the horizontal driving section 44 sequentially outputs, to the signal processing section 48, the pixel signals resulting from the signal processing by the column processing section 43.

The system control section 45 includes, for example, a timing generator generating various timing signals, and drives and controls the vertical driving section 42, the column processing section 43, the horizontal driving section 44, and the like on the basis of the various timing signals generated by the timing generator.

In the pixel array section 41, the pixel driving lines 46 are arranged for the respective pixel rows along the row direction and two vertical signal lines 47 are arranged for each pixel column along the column direction, with respect to the matrix-like pixel array. For example, each of the pixel driving lines 46 transmits a driving signal for performing driving for reading out a signal from the pixel. Note that FIG. 1 illustrates the pixel driving line 46 as one wire but that the pixel driving line 46 is not limited to one wire. One end of the pixel driving line 46 is connected to a corresponding one of the output ends of the vertical driving section 42 for the respective rows.

<Structure of Unit Pixel>

Now, a specific structure of each of the unit pixels 50 arranged in a matrix in the pixel array section 41 will be described.

The pixel 50 includes a photodiode 61 (hereinafter referred to as a PD 61) used as a photoelectric converting element and is configured such that charge generated by the PD 61 is distributed to a tap 51-1 and a tap 51-2. Then, a portion of the charge generated by the PD 61 and then distributed to the tap 51-1 is read out from a vertical signal line 47-1 and output as a detection signal SIG1. Additionally, a portion of the charge distributed to the tap 51-2 is read out from a vertical signal line 47-2 and output as a detection signal SIG2.

The tap 51-1 includes a transfer transistor 62-1, an FD (Floating Diffusion) 63-1, a reset transistor 64, an amplifying transistor 65-1, and a select transistor 66-1. Similarly, the tap 51-2 includes a transfer transistor 62-2, an FD 63-2, the reset transistor 64, an amplifying transistor 65-2, and a select transistor 66-2.

Note that the reset transistor 64 may be shared by the FD 63-1 and the FD 63-2 as depicted in FIG. 3 or provided in each of the FD 63-1 and FD 63-2.

In a case where the reset transistor 64 is provided in each of the FD 63-1 and the FD 63-2, a reset timing can be individually controlled for the FD 63-1 and the FD 63-2, enabling detailed control. In a case where the reset transistor 64 shared by the FD 63-1 and the FD 63-2 is provided, an identical reset timing can be used for the FD 63-1 and the FD 63-2, simplifying the control and a circuit configuration.

In the following description, by way of example, the reset transistor 64 is provided in each of the FD 63-1 and the FD 63-2. The provision of the reset transistor 64 shared by the FD 63-1 and the FD 63-2 will also be appropriately described.

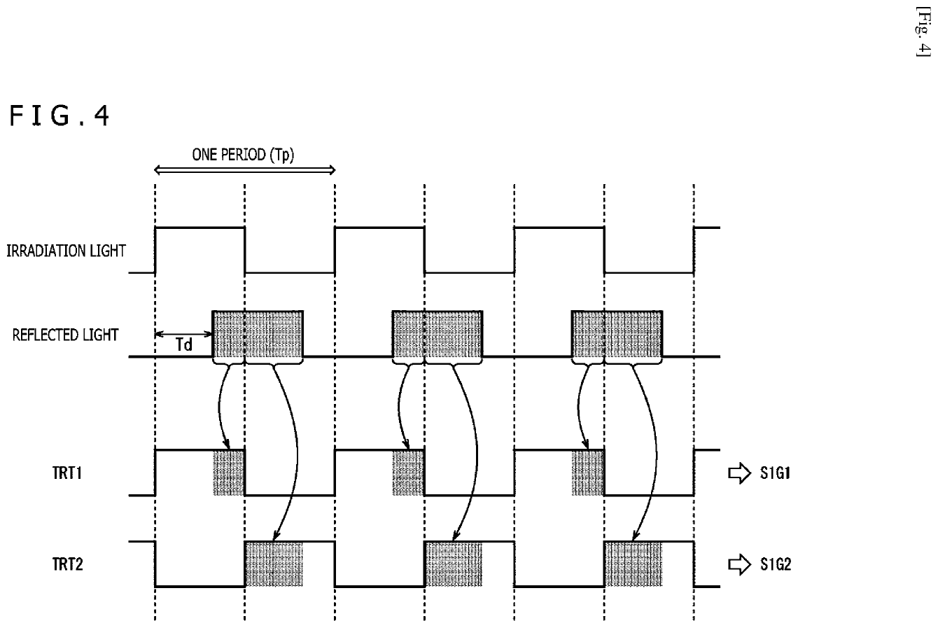

With reference to FIG. 4, distribution of charge in the pixel 50 will be described. Here, the distribution refers to readout of charge stored in the pixel 50 (PD 61) at different timings, meaning that readout is performed for each tap.

As depicted in FIG. 4, irradiation light modulated such that irradiation for an irradiation time T is repeatedly turned on and off (one period=Tp) is output from the light emitting section 14, and reflected light is received at the PD 61 after a delay time Td corresponding to the distance to an object. A transfer control signal TRT1 controls turn-on and turn-off of the transfer transistor 62-1, and a transfer control signal TRT2 controls turn-on and turn-off of the transfer transistor 62-2. As depicted in FIG. 4, the transfer control signal TRT1 has a phase identical to the phase of the irradiation light, whereas the transfer control signal TRT2 has a phase resulting from inversion of the phase of the transfer control signal TRT1.

Accordingly, charge generated by the PD 61 by receiving the reflected light is transferred to the FD 63-1 while the transfer transistor 62-1 is turned on in accordance with the transfer control signal TRT1. Additionally, the charge is transferred to the FD 63-2 while the transfer transistor 62-2 is turned on in accordance with the transfer control signal TRT2. Thus, during a predetermined period when the irradiation with the irradiation light for the irradiation time T is periodically performed, charge transferred via the transfer transistor 62-1 is sequentially stored in the FD 63-1, and charge transferred via the transfer transistor 62-2 is sequentially stored in the FD 63-2. The FD 63 thus functions as a charge storage section storing charge generated by the PD 61.

Then, after the end of the period for charge storage, when the select transistor 66-1 is turned on in accordance with a selection signal SELm1, the charge stored in the FD 63-1 is read out via the vertical signal lines 47-1, and a detection signal SIG1 corresponding to the amount of the charge is output from the light receiving section 12. Similarly, when the select transistor 66-2 is turned on in accordance with a selection signal SELm2, the charge stored in the FD 63-2 is read out via the vertical signal lines 47-2, and a detection signal SIG2 corresponding to the amount of the charge is output from the light receiving section 12.

The charge stored in the FD 63-1 and the charge stored in the FD 63-2 are discharged when the reset transistor 64 is turned on in accordance with a reset signal RST.

In this way, according to the delay time Td, the pixel 50 can distribute, to a tap 51-1 and a tap 51-2, charge generated by the PD 61 on the basis of the received reflected light, thus outputting the detection signal SIG1 and the detection signal SIG2. The delay time Td corresponds to a time taken for light emitted by the light emitting section 14 to travel to the object and then to the light receiving section 12 after reflection by the object, that is, corresponds to the distance to the object. Accordingly, the distance measuring apparatus 10 can determine the distance (depth) to the object according to the delay time Td on the basis of the detection signal SIG1 and the detection signal SIG2.

<Distance Measuring Method Based on Indirect TOF Method>

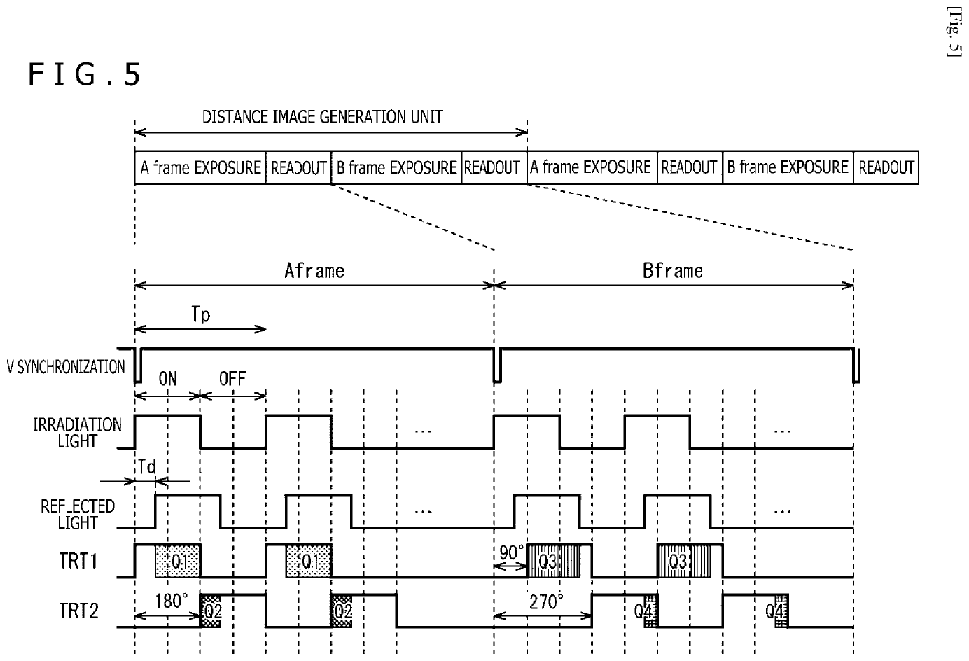

With reference to FIG. 5, the computation of the distance based on the indirect TOF method using a 2 tap method will be described. The 2 tap method uses the two taps 51 to read the charge stored in one PD 61. With reference to FIG. 5, a distance measuring method will be described. In the description with reference to FIG. 5, a 2Tap-4Phase method corresponding to a detection method using two taps and four phases, will be described by way of example.

One frame period during which a distance image is generated is divided into two signal detection periods including an A frame and a B frame. One frame period during which a distance image is generated is set to, for example, approximately 1/30 seconds. Accordingly, the period of the A frame and the period of the B frame are each set to approximately 1/60 seconds.

The light emitting section 14 (FIG. 1) outputs irradiation light modulated such that irradiation for the irradiation time Tp is repeatedly turned on and off (one period=Tp). The irradiation time Tp can be set to, for example, approximately 10 ns. The light receiving section 12 receives reflected light after the delay time Td corresponding to the distance to the object.

In the 4Phase method, the light receiving section 12 uses one of the tap 51-1 or the tap 51-2 to receive light at four timings corresponding to a phase identical to the phase of the irradiation light (Phase0), a phase shifted 90 degrees from the phase of the irradiation light (Phase90), a phase shifted 180 degrees from the phase of the irradiation light (Phase180), and a phase shifted 270 degrees from the phase of the irradiation light (Phase270). Note that the light reception as used herein includes processing starting with the generation of charge by the PD 61 and ending with the transfer of the charge to the FD 63 by turning on the transfer transistor 62.

In FIG. 5, in the A frame, the transfer control signal TRT1 is turned on at the timing of the phase identical to the phase of the irradiation light (Phase0), and the light reception starts through the tap 51-1. Additionally, in the A frame, the transfer control signal TRT2 is turned on at the timing of the phase shifted 180 degrees from the phase of the irradiation light (Phase180), and the light reception starts through the tap 51-2.

In addition, in the B frame, the transfer control signal TRT1 is turned on at the timing of the phase shifted 90 degrees from the phase of the irradiation light (Phase90), and the light reception starts through the tap 51-1. Additionally, in the B frame, the transfer control signal TRT2 is turned on at the timing of the phase shifted 270 degrees from the phase of the irradiation light (Phase270), and the light reception starts through the tap 51-2.

In this case, the tap 51-1 and the tap 51-2 receive light at the timings corresponding to the phases inverted from each other through 180 degrees. Assuming that, in the A frame period, with the irradiation time Tp, charge Q1 is stored in the FD 63-1 of the tap 51-1 at the timing of Phase0, in the A frame period, charge Q1′ corresponding to an accumulated time of the irradiation time Tp during the A frame period is stored in the FD 63-1. Then, the charge Q1′ stored in the FD 63-1 is read out from the FD 63-1 during a readout period as a signal corresponding to the detection signal SIG1. A signal value of the detection signal SIG1 corresponding to the charge Q1′ is assumed to be a signal value I1.

Assuming that, in the A frame period, with the irradiation time Tp, charge Q2 is stored in the FD 63-2 of the tap 51-2 at the timing of Phase180, in the A frame period, charge Q2′ corresponding to the accumulated time of the irradiation time Tp during the A frame period is stored in the FD 63-2. Then, the charge Q2′ stored in the FD 63-2 is read out from the FD 63-2 during the readout period as a signal corresponding to the detection signal SIG2. A signal value of the detection signal SIG2 corresponding to the charge Q2′ is assumed to be a signal value 12.

Assuming that, in the B frame period, with the irradiation time Tp, charge Q3 is stored in the FD 63-1 of the tap 51-1 at the timing of Phase90, in the B frame period, charge Q3′ corresponding to an accumulated time of the irradiation time Tp during the B frame period is stored in the FD 63-1. Then, the charge Q3′ stored in the FD 63-1 is read out from the FD 63-1 during the readout period as a signal corresponding to the detection signal SIG1. A signal value of the detection signal SIG1 corresponding to the charge Q3′ is assumed to be a signal value I3.

Assuming that, in the B frame period, with the irradiation time Tp, charge Q4 is stored in the FD 63-1 of the tap 51-2 at the timing of Phase270, in the B frame period, charge Q4′ corresponding to the accumulated time of the irradiation time Tp during the B frame period is stored in the FD 63-2. Then, the charge Q4′ stored in the FD 63-2 is read out from the FD 63-2 during the readout period as a signal corresponding to the detection signal SIG2. A signal value of the detection signal SIG2 corresponding to the charge Q4′ is assumed to be a signal value I4.

According to a distribution ratio among the signal value I1, the signal value I2, the signal value I3, and the signal value I4, a shift amount θ corresponding to the delay time Td can be detected. Specifically, the delay time Td is determined on the basis of the phase shift amount θ, and thus the distance to a target object is determined from the delay time Td.

The phase shift amount θ is determined by Equation (1), and the distance D to the target object is computed by Equation (2). In Equation (2), C represents a speed of light, and Tp represents a pulse width.

$$\begin{matrix}[ Math . 1 ] & \\ θ = arctan ( \frac{{I}_{1} - {I}_{2}}{{I}_{3} - {I}_{4}} ) & ( 1 ) \\ [ Math . 2 ] & \\ D = \frac{θ}{2 π} \times ( \frac{{T}_{p} C}{2} ) & ( 2 )\end{matrix}$$

In this way, the distance to a predetermined target object can be computed. Such a distance measuring method allows the distance to be measured with effects of ambient light reduced. The descriptions above and below are based on the assumption that only the reflected light of emitted pulsed light is received. However, besides the emitted pulsed light, various types of ambient light are received at the same time. Accordingly, the charge stored in the PD 61 is derived from the emitted pulsed light and the ambient light.

However, the ambient light can be considered to be steady with respect to a pulse period. In a case where the ambient light is steady light, the ambient light is superimposed on the emitted pulsed light as offsets equivalent to the signal value I1, the signal value I2, the signal value I3, and the signal value I4. Accordingly, in the calculation of Equation (1), components (offset components) derived from the ambient light are canceled, leading to no effects on distance measurement results.

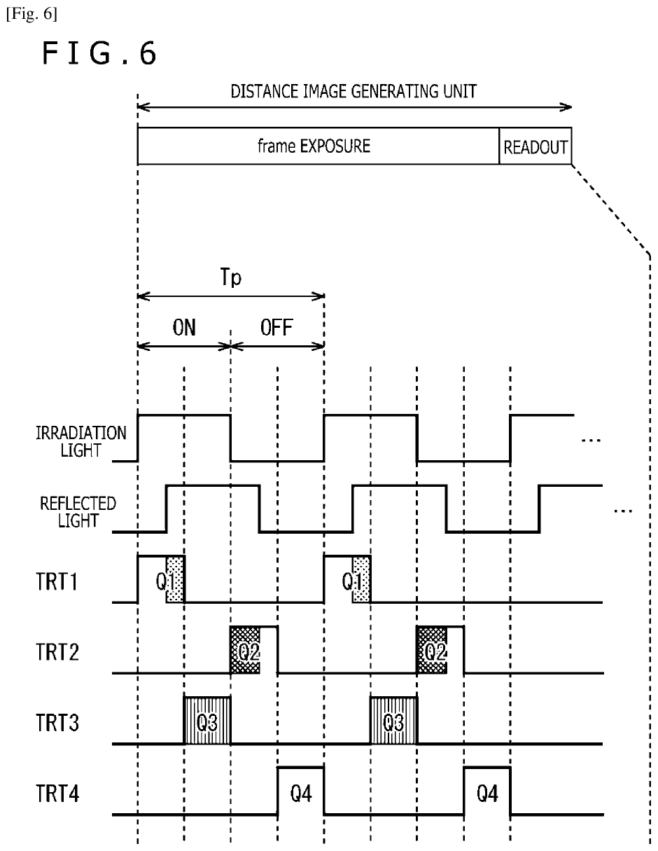

Here, the case of the TOF sensor based on the 2Tap-4Phase method has been described by way of example. However, the present embodiment can be applied to a TOF sensor based on another method. For example, as depicted in FIG. 6, the present embodiment is also applicable to a TOF sensor based on a 4Tap-4Phase method.

FIG. 6 is, similarly to, for example, FIG. 5, a diagram illustrating a distance measuring method and used to describe a distance measuring method based on the 4Tap-4Phase method.

The TOF sensor based on the 4Tap-4Phase method is a sensor including four readout sections each corresponding to the above-described tap 51. In the example illustrated in FIG. 6, the readout sections correspond to four taps including a tap controlled by the transfer control signal TRT1 (referred to as a tap TRT1), a tap controlled by the transfer control signal TRT2 (referred to as a tap TRT2), a tap controlled by a transfer control signal TRT3 (referred to as a tap TRT3), and a tap controlled by a transfer control signal TRT4 (referred to as a tap TRT4).

In one frame corresponding to a distance image generation unit, readout is performed with a phase identical to the phase of the irradiation light (Phase0) using the tap TRT1 and with the phase shifted 180 degrees from the phase of the irradiation light (Phase180) using the tap TRT2.

Additionally, readout is performed with the phase shifted 90 degrees from the phase of the irradiation light (Phase90) using the tap TRT3 and with the phase shifted 270 degrees from the phase of the irradiation light (Phase 270) using the tap TRT4.

In this way, the TOF sensor based on the 4Tap-4Phase method allows processing equivalent to the processing of the 2Tap-4Phase method to be executed using one frame instead of two frames such as the A frame and the B frame.

The present technology described below can be applied both to the TOF sensor based on the 2Tap-4Phase method and to the TOF sensor based on the 4Tap-4Phase method. In the following description, application to the TOF sensor based on the 2Tap-4Phase method will mainly be described by way of example, and application to the TOF sensor based on the 4Tap-4Phase method will appropriately additionally be described.

<Occurrence of Difference in Capacitance between FDs>

As described above, in a case where the distance is computed by distributing, to the FD 63-1 and the FD 63-2, signal charge photo-electrically converted by the PD 61 and determining a difference in signal amount between the signals read out from each of the FD 63-1 and the FD 63-2, the signal amounts may need to be accurately read out. In a case where the FD 63-1 and the FD 63-2 have different capacitances, the signal amounts read out from the two respective FDs 63 may be inaccurate, possibly resulting in reduced accuracy of the difference value computed and thus in reduced accuracy of the computed distance.

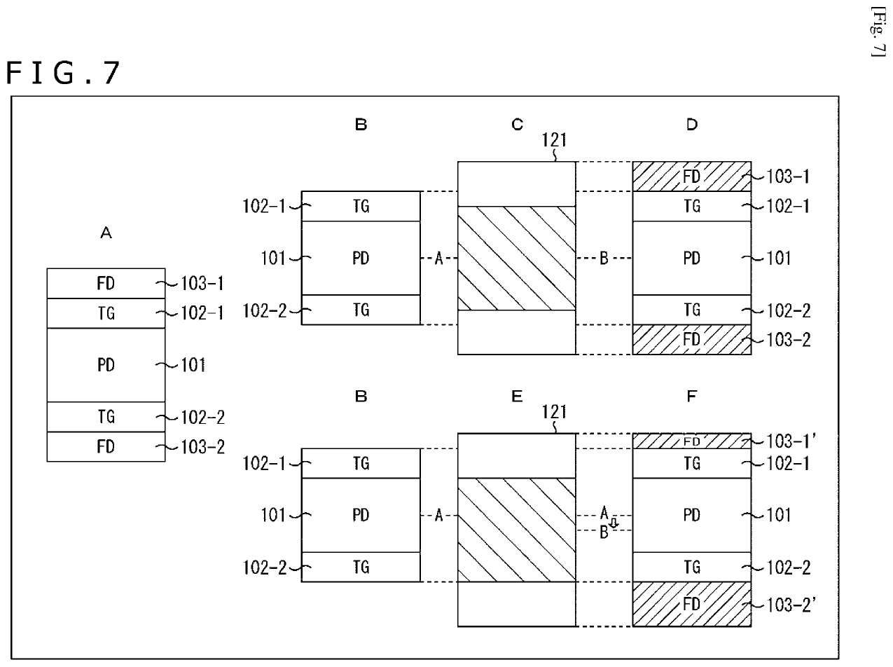

A cause of a difference in capacitance between the FD 63-1 and the FD 63-2 is, for example, variation resulting from the process of manufacture. With reference to FIG. 7, occurrence of a difference in capacitance between the FD 63-1 and the FD 63-2 will be described that is caused by the process of manufacture.

As illustrated at A in FIG. 7, manufacture of a pixel is considered, the pixel including a PD 101 disposed in the center, a transfer transistor gate (hereinafter referred to as a TG) 102-1 disposed above the PD 101, and a TG 102-2 disposed below the PD 101. Additionally, manufacture of a pixel is considered, the pixel including an FD 103-1 disposed above the TG 102-1 and an FD 103-2 disposed below the TG 102-2.

As illustrated at B in FIG. 7, after the PD 101 is formed, the TG 102-1 and the TG 102-2 are respectively formed above and below the PD 101. A mask 121 as illustrated at C in FIG. 7 is formed on the pixel illustrated at B in FIG. 7. The mask 121 is a mask in which an FD 103 region is opened to form the FD 103 region. In the mask 121 used, the region of the PD 101 is masked, and an opening region slightly larger than the FD 103 region to be formed is formed.

After the mask 121 is formed, for example, ion implantation is performed to implant ions into the opening portion to form the FD 103. At this time, even in a case where the opening of the mask 121 is positioned on the TG 102, no ions are implanted into the TG 102, and thus a slightly larger opening may be formed.

As depicted at B in FIG. 7 (upper figure), at C in FIG. 7, and at D in FIG. 7 side by side, the mask 121 is placed in position without displacement and implanted with ions to form the FD 103-1 and the FD 103-2. The placement of the mask 121 in position without displacement means that the mask 121 is placed at a position where the FD 103-1 and FD 103-2 formed have an identical area. This position is designated as a position A. The position A is assumed to be the central position of the PD 101.

Furthermore, in a case where the central position of the mask 121 is assumed to be a position B, the placement of the mask 121 in position without displacement is assumed to refer to the position A and the position B coinciding with each other.

When the mask 121 is placed at a position displaced from the position A and implanted with ions as illustrated at B in FIG. 7 (lower figure), at E in FIG. 7, and at F in FIG. 7 side by side, an FD 103-1′ and an FD 103-2′ formed are different from each other in size. E in FIG. 7 illustrates that the mask 121 is placed at a position displaced from the position A downward. This displacement corresponds to a difference between the position A and the position B. In a case where the difference is out of an allowable range, the FD 103-1′ and FD 103-2′ formed are different from each other in size.

Since the mask 121 is displaced downward, the FD 103-1′ formed is a smaller area than the FD 103-2′. Such displacement of the mask 121 may lead to a difference in area between the FD 103-1′ and the FD 103-2′, resulting in a structure in which the FD 103-1′ and the FD 103-2′ are different from each other in conversion efficiency. Note that in the above description, the mask 121 is displaced in the up-down direction by way of example but that, in a case where the mask 121 is displaced in the lateral direction or an oblique direction, a difference in area may also occur between the FD 103-1′ and the FD 103-2′, resulting in a structure in which the FD 103-1′ and the FD 103-2′ are different from each other in conversion efficiency.

Thus, a configuration will be described below in which even with possible displacement of the mask during manufacture, a plurality of FD regions has an equal area and thus the same conversion efficiency.

### First Embodiment

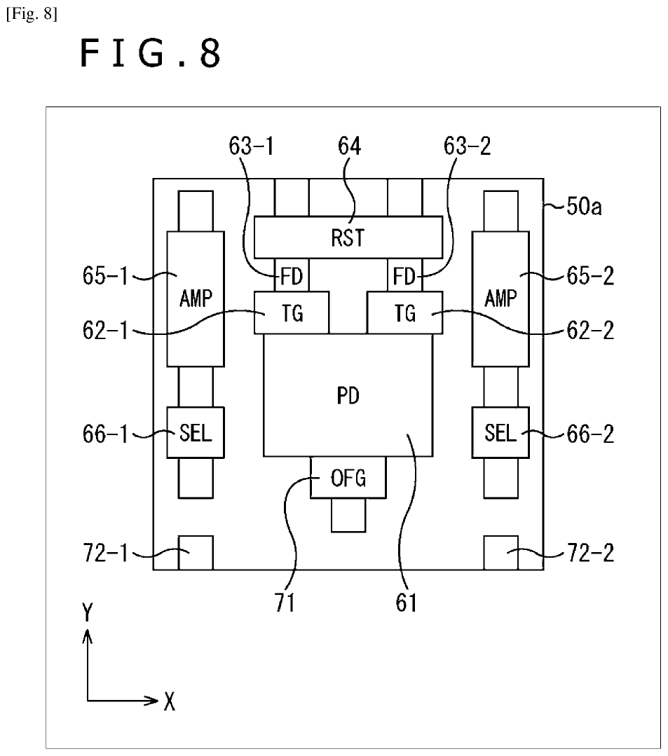

FIG. 8 is a plan view depicting a configuration of a pixel 50a according to a first embodiment. In FIG. 8 and the following description, the lateral direction in the figure is assumed to be an X-axis direction, and the up-down direction in the figure is assumed to be a Y-axis direction. Additionally, the X direction in FIG. 8 corresponds to the row direction (horizontal direction) in FIG. 2, and the Y direction in FIG. 8 corresponds to the column direction (vertical direction) in FIG. 2.

As depicted in FIG. 8, the PD 61 is provided in the region of a central portion of the rectangular pixel 50a. The TG 62-1 and the TG 62-2 are provided above the PD 61 (on an upper side of the PD 61) in the figure. The TG 62-1 is a gate portion of the transfer transistor 62-1, and the TG 62-2 is a gate portion of the transfer transistor 62-2.

The TG 62-1 and the TG 62-2 are provided adjacent to one of the four sides of the PD 61. In the example illustrated in FIG. 8, the TG 62-1 and the TG 62-2 are arranged on the upper side of the PD 61 side by side in the X-axis direction.

The FD 63-1 is provided above the TG 62-1, and the FD 63-2 is provided above the TG 62-2. A gate of one reset transistor 64 (hereinafter referred to as the RST 64) is provided above the FD 63-1 and the FD 63-2.

The amplifying transistor 65-1 (a gate of the amplifying transistor 65-1), amplifying the signal amount from the FD 63-1, is provided on the left side of the FD 63-1 in a vertically (Y-axis direction) long form. The select transistor 66-1 (a gate of the select transistor 66-1) is provided below the amplifying transistor 65-1.

The amplifying transistor 65-2 (a gate of the amplifying transistor 65-2), amplifying the signal amount from the FD 63-2, is provided on the right side of the FD 63-2 in a vertically (Y-axis direction) long form. The select transistor 66-2 (a gate of the select transistor 66-2) is provided below the amplifying transistor 65-2.

A well contact 72-1 is provided below the select transistor 66-1, and a well contact 72-2 is provided below the select transistor 66-2. A discharge transistor (OFG) 71 is provided below the PD 61. The discharge transistor 71 is an overflow gate for anti-blooming.

The arrangement depicted in FIG. 8 and in the following description is an example and is not a description indicating a limitation. Additionally, the example illustrated in FIG. 8 and in the following description illustrates a configuration with the discharge transistor 71, but the discharge transistor 71 may be omitted from the configuration.

In the example illustrated in FIG. 8, the TG 62-1, the FD 63-1, the amplifying transistor 65-1, and the select transistor 66-1 are disposed in a line symmetric relationship with the TG 62-2, the FD 63-2, the amplifying transistor 65-2, and the select transistor 66-2, with respect to a center lines (not illustrated) between the TG 62-1 and the TG 62-2.

Although wiring is not depicted in FIG. 8, the FD 63-1 and the amplifying transistor 65-1 are connected together, and the signal amount from the FD 63-1 is supplied to the amplifying transistor 65-1. Additionally, the FD 63-2 and the amplifying transistor 65-2 are connected together, and the signal amount from the FD 63-2 is supplied to the amplifying transistor 65-2.

As described above, the line symmetric configuration enables the length of the wiring between the FD 63-1 and the amplifying transistor 65-1 to be made substantially identical to the length of the wiring between the FD 63-2 and the amplifying transistor 65-2. Additionally, for the other wiring, lateral object wiring allows an identical length to be achieved.

In the pixel 50a depicted in FIG. 8, the FD 63-1 is provided between the TG 62-1 and the RST 64, and the FD 63-2 is provided between the TG 62-2 and the RST 64. The distance between the TG 62-1 and the RST 64 is identical to the distance between the TG 62-2 and the RST 64.

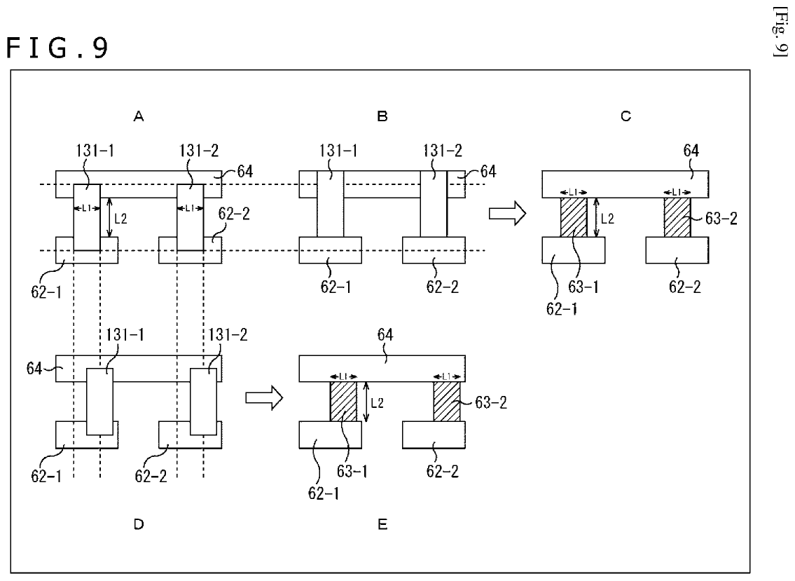

In a case where the width of the FD 63-1 is identical to the width of the FD 63-2, the size (area) of the region of the FD 63-1 is identical to the size (area) of the region of the FD 63-2. The width of the FD 63-1 and the width of the FD 63-2 are set to be identical by a mask during manufacture, so that the region of the FD 63-1 is identical in size (area) to the region of the FD 63-2. This will be described with reference to FIG. 9.

A to E in FIG. 9 depict the TG 62-1, the TG 62-2, and the RST 64, included in the pixel 50a depicted in FIG. 8. The TG 62-1, the TG 62-2, and the RST 64 are formed in a position relationship depicted in FIG. 9 before the FD 63 is formed. A in FIG. 9 depicts an opening 131 of the mask used to form the FD 63.

As depicted at A in FIG. 9, the mask is a mask in which the FD 63 region is opened to form the FD 63 region. An opening 131-1 and an opening 131-2 in the mask are regions slightly larger than the FD 63-1 and the FD 63-2, respectively.

After the mask with the opening 131-1 and the opening 131-2 is formed, for example, ion implantation is performed to implant ions into the opening portion, thereby forming each of the FD 63-1 and the FD 63-2. At this time, even in a case where the opening 131 of the mask is positioned on the TG 62 or the RST 64, no ions are implanted into the TG 62 or the RST 64, and thus a slightly larger opening may be formed.

The state depicted at A in FIG. 9 is assumed to be an optimum state. As depicted at A in FIG. 9, the optimum state is assumed to be a state in which an overlapping portion between the opening 131-1 and the TG 62-1 is positioned at a central portion of the TG 62-1 and in which an overlapping portion between the opening 131-2 and the TG 62-2 is positioned at a central portion of the TG 62-2.

When the FD 63 is formed in the state depicted at A in FIG. 9, the FD 63-1 is a central portion of an upper side of the TG 62-1 and is formed between the TG 62-1 and the RST 64 as depicted at C in FIG. 9. Likewise, the FD 63-2 is a central portion of an upper side of the TG 62-2 and is formed between the TG 62-2 and the RST 64. Additionally, the FD 63-1 and FD 63-2 formed have an identical size.

As depicted at A in FIG. 9, both the opening 131-1 and the opening 131-2 is assumed to have a width L1, and the distance between a lower side of the RST 64 in the figure and an upper side of the TG 62-1 (TG 62-2) in the figure is assumed to be a height L2. In this case, as depicted at C in FIG. 9, the area of the FD 63-1 formed is (width L1×height L2), and the area of the FD 63-2 is (width L1×height L2). Accordingly, the FD 63-1 and FD 63-2 formed are identical in size.

B in FIG. 9 illustrates that the mask is displaced upward. Even in a case where the mask is displaced upward, the position relationship between the TG 62 and the RST 64 remains unchanged, with the distance between the TG 62 and the RST 64 remaining equal to the height L2. Additionally, the width of the opening 131 is the width L1. Accordingly, even in a case where the mask is displaced upward as depicted at B in FIG. 9, the FD 63-1 and the FD 63-2 each having an area of (width L1×height L2) are formed as depicted at C in FIG. 9.

Specifically, even in a case where the mask is displaced upward with respect to the optimum state, the areas of the FD 63-1 and the FD 63-2 formed are identical in size. Even in a case where the mask is displaced downward, the areas of the FD 63-1 and the FD 63-2 formed are identical in size.

D in FIG. 9 illustrates that the mask is displaced leftward. Even in a case where the mask is displaced leftward, the position relationship between the TG 62 and the RST 64 remains unchanged, with the distance between the TG 62 and the RST 64 remaining equal to the height L2. Additionally, the width of the opening 131 is the width L1. Accordingly, even in a case where the mask is displaced leftward as depicted at D in FIG. 9, the FD 63-1 and the FD 63-2 each having an area of (width L1×height L2) are formed as depicted at E in FIG. 9.

Specifically, even in a case where the mask is displaced leftward with respect to the optimum state, the areas of the FD 63-1 and the FD 63-2 formed are identical in size. Even in a case where the mask is displaced rightward, the areas of the FD 63-1 and the FD 63-2 formed are identical in size.

In this way, even in a case where the mask is displaced upward, downward, leftward, or rightward, the areas of the FD 63-1 and the FD 63-2 formed are identical in size.

As described with reference to FIG. 7, in a case where a displaced mask causes a difference in area among the plurality of FDs 63 formed, then in the resultant structure, the FDs 63 are different from each other in conversion efficiency. However, as described with reference to FIG. 9, even in a case where the mask is displaced, the present technology prevents a possible difference in area among the plurality of FDs 63 formed, allowing prevention of possible formation of structure in which the FDs 63 are different from each other in conversion efficiency.

As described with reference to FIG. 8 and FIG. 9, even in a case where the mask is displaced from a predetermined position during manufacture, a possible difference in area is prevented among the plurality of FDs 63 formed. One condition for such a structure is that the TG 62 and the RST 64 are formed parallel to each other with an in-variable distance between the TG 62 and the RST 64 (distance represented as the height L2 in FIG. 9).

In other words, a gate of a transistor different from the TG 62 is formed parallel to the TG 62, and the FD 63 is formed between the TG 62 and the gate. This allows a plurality of the FDs 63 to be formed with no difference in area among the plurality of FDs 63 formed.

Furthermore, in other words, when the FD 63 is formed by ion implantation or the like, a region with no ions implanted is formed at a position parallel to the TG 62, and the FD 63 is formed between the TG 62 and the region paired with the TG 62. This allows a plurality of the FDs 63 to be formed with no difference in area among the plurality of FDs 63 formed.

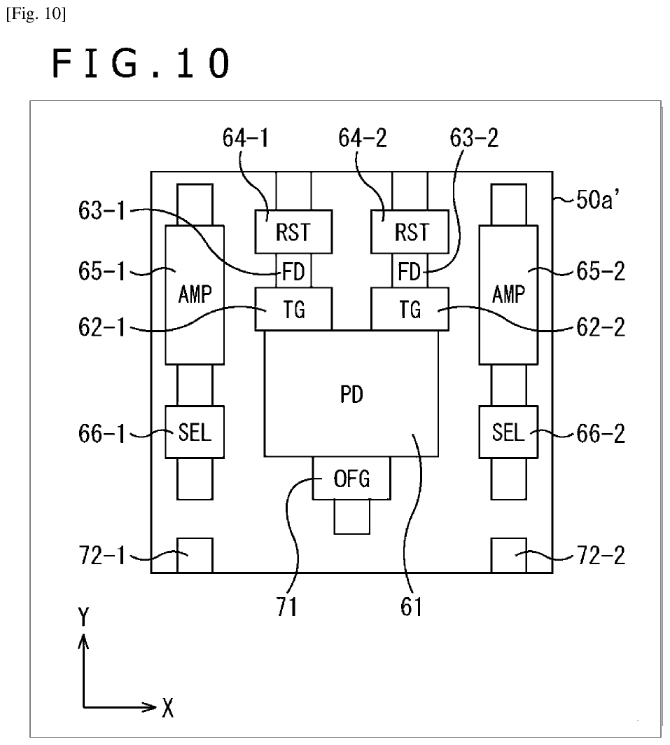

FIG. 10 is a plan view depicting another configuration example of the pixel 50a depicted in FIG. 8. In comparison, a pixel 50a′ depicted in FIG. 10 differs from the pixel 50a depicted in FIG. 8 in that the RST 64 of the pixel 50a includes an RST 64-1 and an RST 64-2, with the other portions of the pixel 50′ similar to the corresponding portions of the pixel 50. The similar portions are denoted by the same reference signs, and description of these portions is omitted.

The pixel 50a′ depicted in FIG. 10 includes the RST 64-1 paired with the TG 62-1 and the RST 64-2 paired with the TG 62-2. In other words, the pixel 50a′ includes the separate RSTs 64 including the RST 64-1 resetting the FD 63-1 and the RST 64-2 resetting the FD 63-2.

The RST 64-1 and the RST 64-2 may be connected together by wiring to function as one RST 64. Such a configuration is identical to the configuration of the pixel 50a depicted in FIG. 8.

The gate installed parallel to the TG 62 can be provided for each of the plurality of FDs 63 as in the pixel 50a′ depicted in FIG. 10, or a gate shared by the plurality of FDs 63 may be provided as in the pixel 50a depicted in FIG. 8. In a case where the gate is provided for each of the plurality of FDs 63, the TGs 62 and the gates are provided such that the distance between each TG 62 and the corresponding gate is the same.

### Second Embodiment

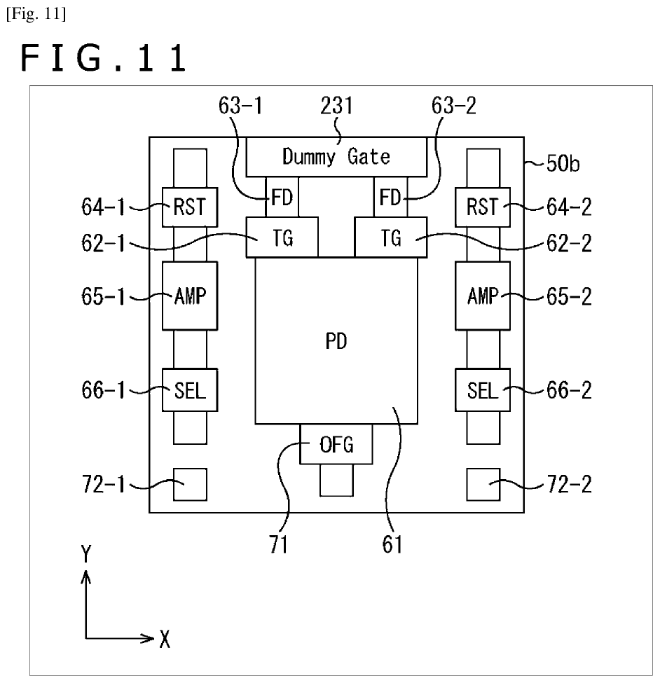

FIG. 11 is a plan view depicting a configuration of a pixel 50b according to a second embodiment. The pixel 50b depicted in FIG. 11 includes a dummy gate 231. The pixel 50b depicted in FIG. 11 is provided with the dummy gate 231 in a region corresponding to a region where the RST 64 of the pixel 50a depicted in FIG. 8 is positioned.

As in the pixel 50b, the gate paired with the TG 62 may be other than the gate of the reset transistor, and FIG. 11 illustrates that the gate paired with the TG 62 is the dummy gate 231. The dummy gate 231 is a gate to which no function is assigned but which is provided to prevent a possible difference in area among the plurality of FDs 63 caused by mask displacement during manufacture.

In the pixel 50b, an RST 232-1 is provided on the left side of the FD 63-1 in the figure, and an RST 232-2 is provided on the right side of the FD 63-2 in the figure. The position where the RST 232 is provided can be appropriately varied.

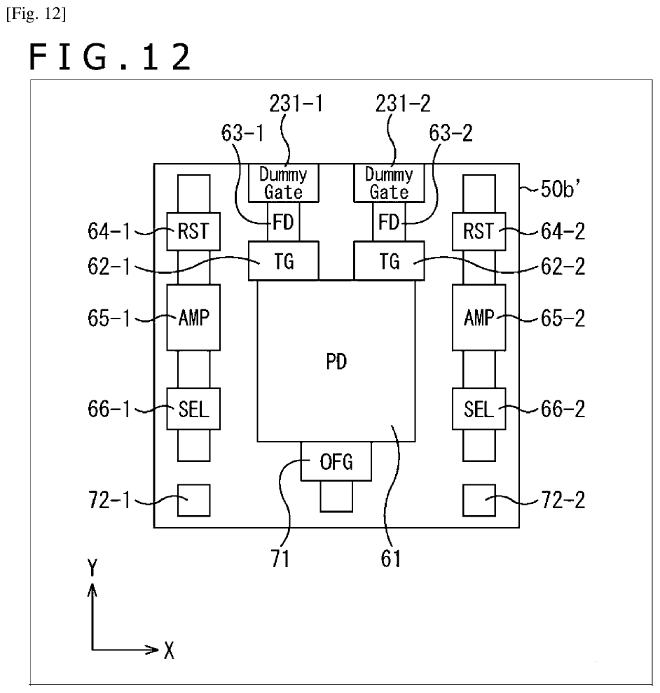

The dummy gate 231 may include a plurality of dummy gates 231 such as a dummy gate 231-1 and a dummy gate 231-2, in other words, as many dummy gates 231 as the FDs 63 may be provided, as depicted in FIG. 12.

A pixel b and a pixel b′ depicted in FIG. 11 and FIG. 12 are also configured such that the TG 62 and the dummy gate 231 are provided parallel to each other, with the distance between the TG 62 and the dummy gate 231 kept constant. Accordingly, the plurality of FDs 63 each provided between the TG 62 and the dummy gate 231 has an identical size in area.

### Third Embodiment

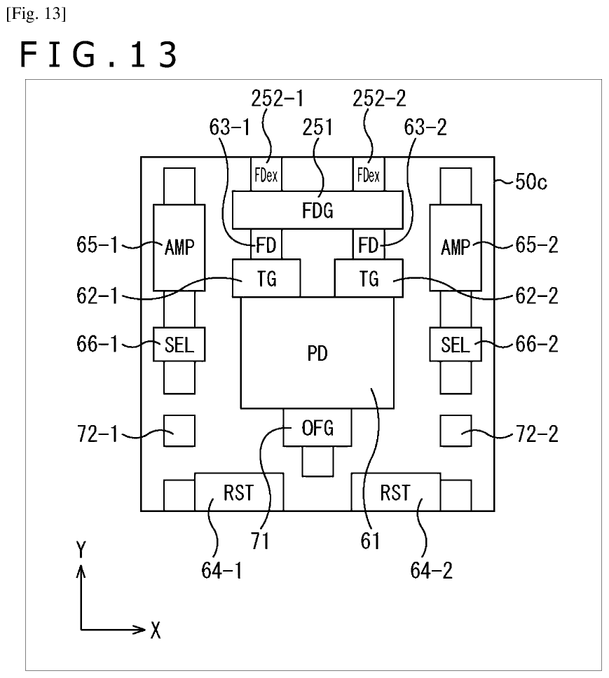

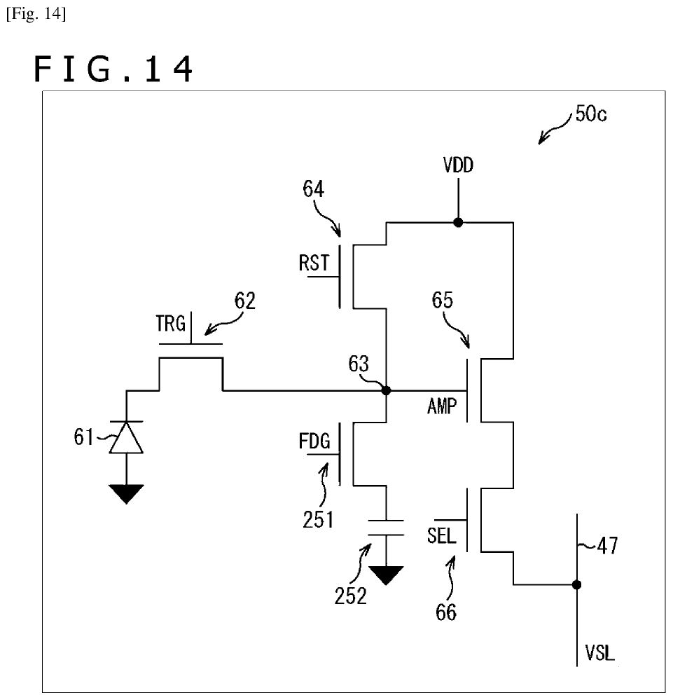

FIG. 13 is a plan view depicting a configuration of a pixel 50c according to a third embodiment. The pixel 50c depicted in FIG. 13 includes a transistor for conversion efficiency switching. In FIG. 13, a gate of the transistor for conversion efficiency switching 251 is represented as FDG 251. Here, a circuit diagram depicted in FIG. 14 is referenced for description of the pixel 50c provided with the transistor for conversion efficiency switching 251.

FIG. 14 depicts a circuit configuration of a general pixel 50c including the transistor for conversion efficiency switching 251 (circuit configuration related to one of the FDs 63 in the pixel 50c) to describe the pixel 50c provided with the transistor for conversion efficiency switching 251.

The pixel 50c depicted in FIG. 14 is a pixel including the PD 61, the transfer transistor 62, the FD 63, the reset transistor 64, the amplifying transistor 65, and the select transistor 66, and additionally including the transistor for conversion efficiency switching 251 and an additional capacitance section 252.

The PD 61 is a photoelectric converting element. The PD 61 receives light from a subject, generates charge corresponding to the amount of received light by performing photoelectric conversion, and stores the charge. The transfer transistor 62 is provided between the PD 61 and the FD 63, and transfers the charge stored in the PD 61 to the FD 63 in accordance with a driving signal TRG applied to a gate electrode of the transfer transistor 62.

The FD 63 is a floating diffusion region (FD) that converts, into an electric signal, for example, a voltage signal, the charge transferred from the PD 61 via the transfer transistor 62, and then outputs the voltage signal. The FD 63 connects to the reset transistor 64 and to the vertical signal line 47 via the amplifying transistor 65 and the select transistor 66.

Furthermore, the FD 63 also connects via the transistor for conversion efficiency switching 251 to the additional capacitance section 252, which is a floating diffusion region (FD) converting charge into an electric signal, for example, a voltage signal. Note that the additional capacitance section 252 is a floating diffusion region (FD) but is represented using a circuit symbol for a capacitor because the additional capacitance section 252 performs capacitive operation.

The transistor for conversion efficiency switching 251 is turned on and off in accordance with the driving signal FDG to switch between a connection state in which the FD 63 and the additional capacitance section 252 are electrically connected together and a connection state in which the FD 63 and the additional capacitance section 252 are electrically disconnected from each other. Specifically, the driving signal FDG is supplied to a gate electrode included in the transistor for conversion efficiency switching 251, and turning on the driving signal FDG increases the potential immediately below the transistor for conversion efficiency switching 251, electrically connecting the FD 63 and the additional capacitance section 252 together.

In contrast, turning off the driving signal FDG reduces the potential immediately below the transistor for conversion efficiency switching 251, electrically disconnecting the FD 63 and the additional capacitance section 252 from each other. Accordingly, turning on and off the driving signal FDG allows capacitance to be added to the FD 63 and to change the sensitivity of the pixel. Specifically, assuming that ΔQ represents the amount of change in charge stored, that ΔV represents the corresponding change in voltage, and that C represents a capacitance value, a relationship ΔV=ΔQ/C holds true.

Now, it is assumed that the FD 63 has a capacitance value of CFD and that the additional capacitance section 252 has a capacitance value of CFD2. Then, with the driving signal FDG on, a region of the pixel where the signal level is read out has a capacitance value C of CFD+CFD2. In contrast, turning off the driving signal FDG changes the capacitance value C to CFD, so that the sensitivity (amount of change in voltage: FD conversion efficiency) of the voltage increases to the amount of change in charge.

In this way, in the pixel 50c, turning on and off the driving signal FDG appropriately changes the sensitivity of the pixel. For example, turning on the driving signal FDG electrically connects the additional capacitance section 252 to the FD 63, thus storing a portion of the charge transferred from the PD 61 to the FD 63, not only in the FD 63 but also in the additional capacitance section 252.

The reset transistor 64 is an element appropriately initializes (resets) the respective regions from the FD 63 to the additional capacitance section 252, and includes a drain connected to a power supply with a power supply voltage VDD and a source connected to the FD 63. A driving signal RST is applied to a gate electrode of the reset transistor 64 as a reset signal. Additionally, setting the driving signal RST to an active state brings the reset transistor 64 into an electrically connected state to reset the potentials of the FD 63 and the like to the level of the power supply voltage VDD. In other words, the FD 63 and the like are initialized.

The amplifying transistor 65 includes a gate electrode connected to the FD 63 and a drain connected to the power supply with the power supply voltage VDD, and is used as an input section of a source follower circuit that reads out the charge obtained by performing photoelectric conversion in PD 61. Specifically, the amplifying transistor 65 includes a source connected to the vertical signal lines 47 via the select transistor 66, thus forming the source follower circuit along with a constant current source connected to one end of the vertical signal line 47.

The select transistor 66 is connected between the source of the amplifying transistor 65 and the vertical signal line 47, and a driving signal SEL is supplied to a gate electrode of the select transistor 66 as a selection signal. Setting the driving signal SEL to the active state brings the select transistor 66 into the electrically connected state, in turn bringing, into a selected state, the pixel provided with the select transistor 66. In the pixel brought into the selected state, a signal output from the amplifying transistor 65 is read out into the column processing section 23 via the vertical signal lines 47.

The description returns to the one referring to the pixel 50c depicted in FIG. 13. The pixel 50c depicted in FIG. 13 includes the gate of the transistor for conversion efficiency switching 251 (hereinafter referred to as the FDG 251) and also includes the additional capacitance section 252 (hereinafter referred to as the FDex 252).

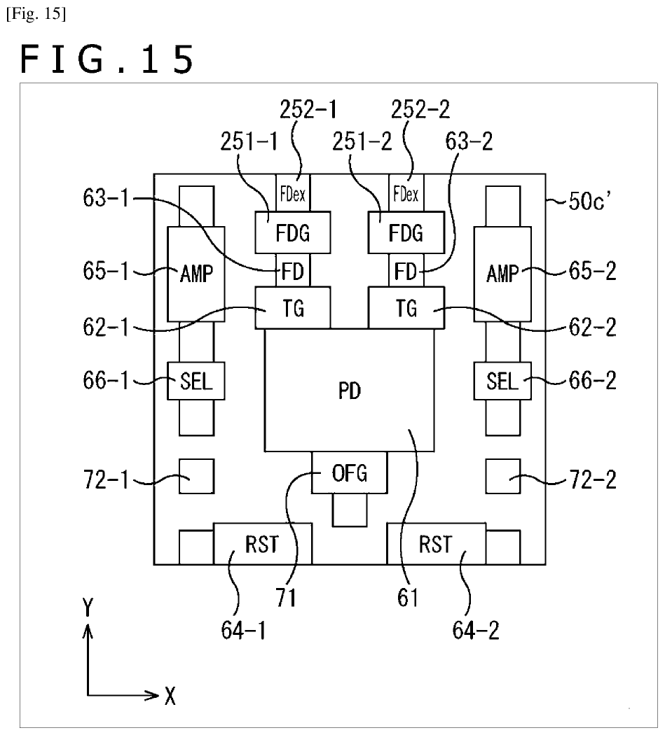

The pixel 50c depicted in FIG. 13 includes one FDG 251 shared by the TG 62-1 and the TG 62-2. However, similar to a pixel 50c′ depicted in FIG. 15, the pixel 50c may include an FDG 251-1 paired with the TG 62-1 and an FDG 251-2 paired with the TG 62-2.

The following description refers to the pixel 50c′ depicted in FIG. 15. The FD 63-1 is provided between the TG 62-1 and the FDG 251-1, and an FDex 252-1 connected to the FD 63-1 is provided above the FDG 251-1 in the figure. Similarly, the FD 63-2 is provided between the TG 62-2 and the FDG 251-2, and an FDex 252-2 connected to the FD 63-2 is provided above the FDG 251-2 in the figure.

A pixel c and a pixel c′ depicted in FIG. 13 and FIG. 15 are also configured such that the TG 62 and the FDG 251 are provided parallel to each other, with the distance between the TG 62 and the FDG 251 kept constant. Accordingly, the plurality of FDs 63 each provided between the TG 62 and the FDG 251 has an identical area in size.

Additionally, the pixel 50c′ is connected to the FD 63, and the FDex 252, which functions as a part of the floating diffusion region, is provided. As may FDexes 252 as the FDs 63 are provided. A difference in area among the plurality of FDexes 252 results in a difference in capacitance between the FDs 63. Accordingly, the plurality of FDexes 252 may preferably have an identical area, and the pixel 50c (pixel 50c′) has such a configuration.

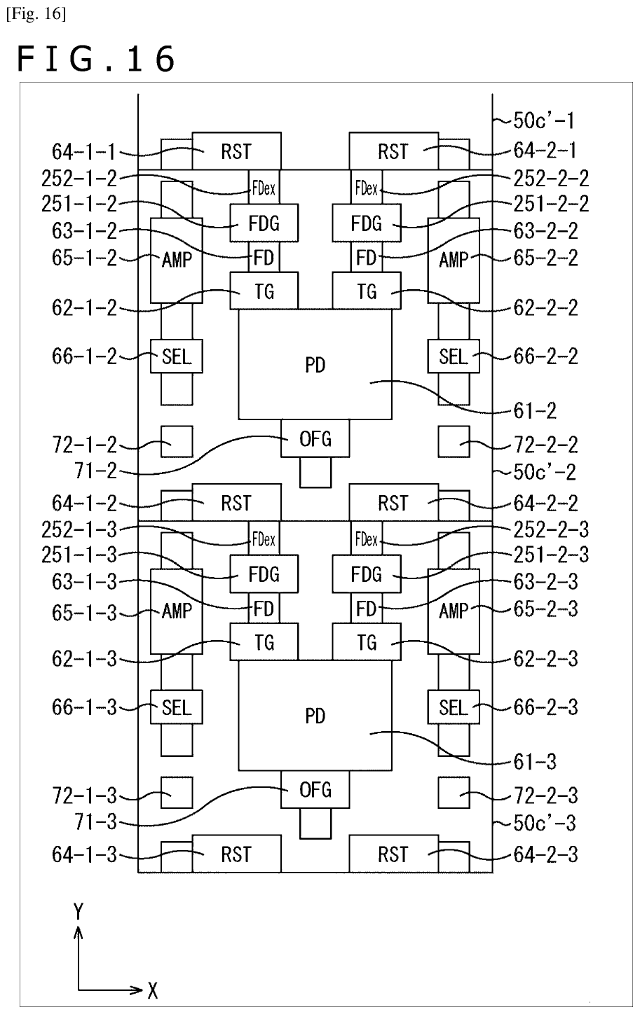

In the pixel 50c′ depicted in FIG. 15, the RST 64-1 and the RST 64-2 are provided on a lower side of the pixel 50c′. On the other hand, the FDex 252-1 and the FDex 252-2 are provided on an upper side of the pixel 50c′. A plurality of pixels 50c′ is two-dimensionally arranged in the pixel array section 41 (FIG. 2). Three pixels arranged in the up-down direction are depicted in FIG. 16. FIG. 16 depicts (a part of) a pixel 50c′-1, a pixel 50c′-2, and a pixel 50c′-3 arranged in the up-down direction.

An RST 64-1-1 of the pixel 50c′-1 is provided at a position adjacent to an FDex 252-1-2 of the pixel 50c′-2. Additionally, the RST 64-1-1 of the pixel 50c′-1 and the FDex 252-1-2 of the pixel 50c′-2 are provided parallel to each other (the distance between the RST 64-1-1 and the FDex 252-1-2 is constant). Specifically, the FDex 252-1-2 is positioned between the two gates of the RST 64-1-1 of the pixel 50c′-1 and the FDG 251-1-2 of the pixel 50c′-2.

Similarly, an RST 64-2-1 of the pixel 50c′-1 is provided at a position adjacent to an FDex 252-2-2 of the pixel 50c′-2. Additionally, the RST 64-2-1 of the pixel 50c′-1 and the FDG 251-2-2 of the pixel 50c′-2 are provided parallel to each other (the distance between the RST 64-2-1 and the FDG 251-2-2 is constant). Specifically, the FDex 252-2-2 is positioned between the two gates of the RST 64-2-1 of the pixel 50c′-1 and the FDG 251-2-2 of the pixel 50c′-2.

Accordingly, the FDex 252-1-2 and the FDex 252-2-2 have an equal height and an equal width, and have an identical area. In other words, in this case, the FDex 252-1-2 and FDex 252-2-2 provided in the pixel 50c′-2 are identical in size.

Similarly, an FDex 252-1-3 of the pixel 50c′-3 is positioned between the RST 64-1-2 of the pixel 50c′-2 and the FDG 251-1-3 of the pixel 50c′-3. An FDex 252-2-3 of the pixel 50c′-3 is positioned between the RST 64-2-2 of the pixel 50c′-2 and the FDG 251-2-3 of the pixel 50c′-3. Accordingly, the FDex 252-1-3 and FDex 252-2-3 provided in the pixel 50c′-3 are identical in size.

In this way, the gate provided in the adjacent pixel and the gate provided in the subject gate are provided parallel to each other, with the FDex 252 provided between the gates. Then, similarly to the FD 63, the FDex 252 can be provided with no difference in area.

### Fourth Embodiment

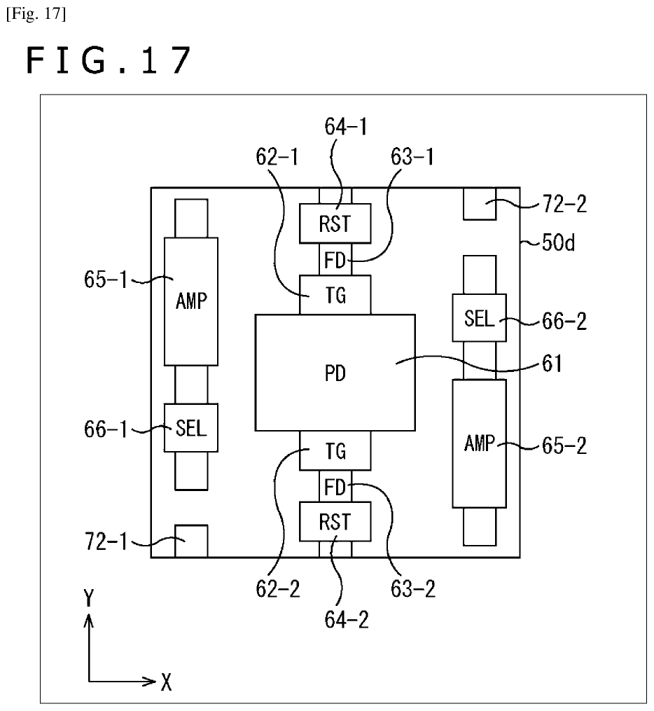

FIG. 17 is a plan view depicting a configuration of a pixel 50d according to a fourth embodiment. The pixel 50d depicted in FIG. 17 has a configuration obtained by modifying the pixel 50a according to the first embodiment depicted in FIG. 10.

The pixel 50a′ depicted in FIG. 10 represents an example in which the tap including the TG 62-1, the FD 63-1, and the RST 64-1 and the tap including the TG 62-2, the FD 63-2, and the RST 64-2 are disposed in the lateral direction, in other words, the taps are disposed on one side of the PD 61. As depicted in FIG. 17, the tap including the TG 62-1, the FD 63-1, and the RST 64-1 and the tap including the TG 62-2, the FD 63-2, and the RST 64-2 may be disposed in the vertical direction, in other words, the taps may be disposed on two side of the PD 61.

A pixel 50d depicted in FIG. 17 includes the TG 62-1, the FD 63-1, and the RST 64-1 provided on the upper side of the PD 61 in the figure, and the TG 62-2, the FD 63-2, and the RST 64-2 provided on a lower side of the PD 61 in the figure.

Also in the pixel 50d depicted in FIG. 17, the FD 63-1 and the FD 63-2 can be formed without any difference in area even in a case where the mask is displaced in the up-down direction or the lateral direction during manufacture.

Note that, in the example described with reference to FIG. 17, the TG 62 and the RST 64 are paired with the FD 63 provided between the TG 62 and the RST 64, but that this configuration may be combined with the pixel 50b according to the second embodiment to include the dummy gate 231 disposed in the pixel instead of the RST 64. Alternatively, the configuration may be combined with the pixel 50c according to the third embodiment to include the FDG 251 disposed in the pixel instead of the RST 64.

<Wiring>

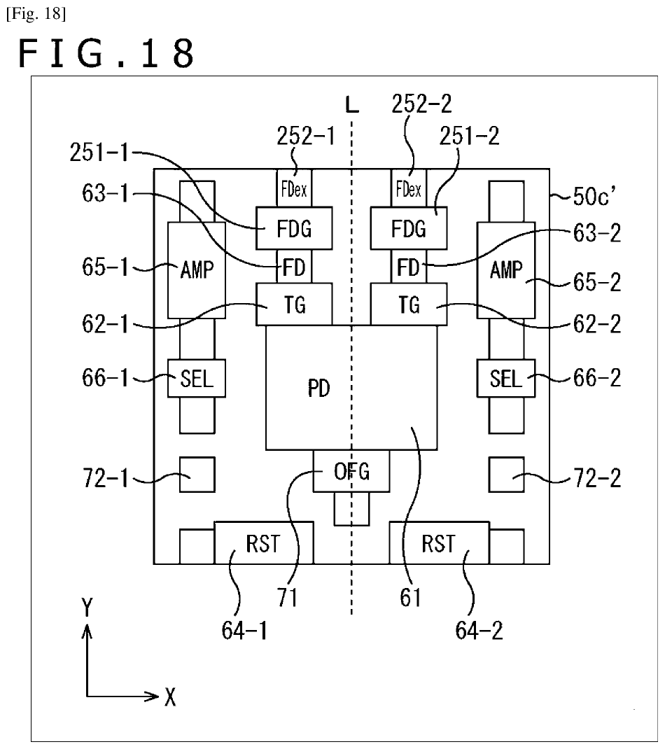

In the pixel 50a according to the first embodiment, the pixel 50b according to the second embodiment, and the pixel 50c according to the third embodiment, transistors such as the amplifying transistor 65 and the select transistor 66 are line-symmetrically disposed as depicted in FIG. 18.

FIG. 18 illustrates the pixel 50c′ according to a third embodiment. In the pixel 50c′ depicted in FIG. 18, the TG 62-1, the FD 63-1, the FDG 251-1, the FDex 252-1, the amplifying transistor 65-1, the select transistor 66-1, a well contact 72-1, and an RST 251-1 are disposed in a line symmetric relationship with the TG 62-2, the FD 63-2, the FDG 251-2, the FDex 252-2, the amplifying transistor 65-2, the select transistor 66-2, a well contact 72-2, and an RST 251-2, with respect to a line L depicted by a dashed line.

The line symmetric arrangement as described above allows the wiring connecting the transistors to have an identical length on the right and left sides (identical length on the right and left sides within the tap 51). For example, the length of the wiring connecting the FD 63-1 and the amplifying transistor 65-1 can be made identical to the length of the wiring connecting the FD 63-2 and the amplifying transistor 65-2. The wiring with the same length allows the respective FDs 63 to have the same conversion efficiency. This enables the apparatus to be made robust against variation during manufacture.

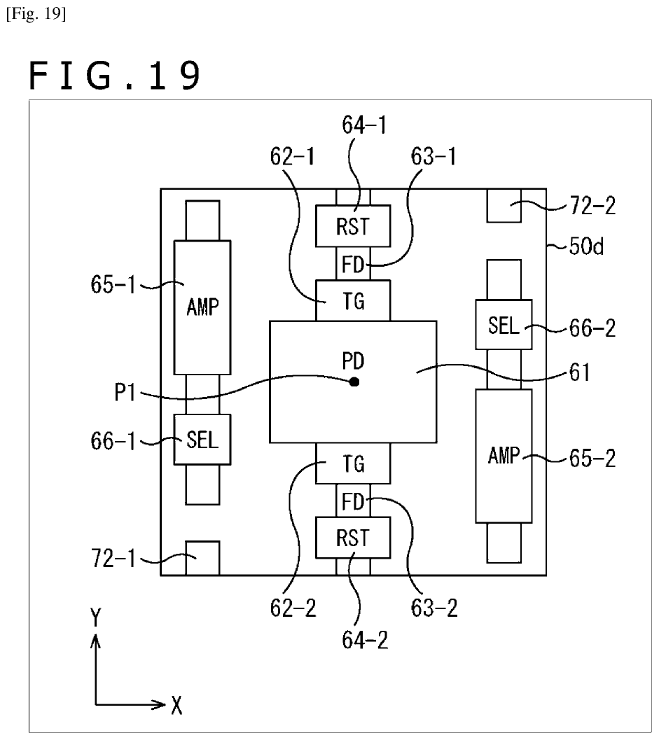

In a case where the TG 62 and the FD 63 are disposed in the vertical direction as in the pixel 50d according to the fourth embodiment, the amplifying transistor 65 and the like are point-symmetrically disposed as depicted in FIG. 19. FIG. 19 illustrates a pixel 50d according to the fourth embodiment.

The TG 62-1, the FD 63-1, the FDG 251-1, the FDex 252-1, the amplifying transistor 65-1, the select transistor 66-1, the well contact 72-1, and the RST 251-1 are disposed in a point symmetric relationship with the TG 62-2, the FD 63-2, the FDG 251-2, the FDex 252-2, the amplifying transistor 65-2, the select transistor 66-2, the well contact 72-2, and the RST 251-2, around a point P1 depicted on the PD 61 of the pixel 50d depicted in FIG. 19.

The point symmetric arrangement as described above allows the wiring connecting the transistors to have an identical length with the tap 51. For example, the length of the wiring connecting the FD 63-1 and the amplifying transistor 65-1 can be made identical to the length of the wiring connecting the FD 63-2 and the amplifying transistor 65-2. The wiring with the same length allows the respective FDs 63 to have the same conversion efficiency. This enables the apparatus to be made robust against variation during manufacture.

Note that the line symmetric or point symmetric arrangement of the transistors and the like is advantageous, for example, in that variation is eliminated as described above, but that the range of application of the present technology is not limited to the line symmetric or point symmetric arrangement of the transistors and the like.

Additionally, the arrangements of the transistors and the like illustrated above and below are examples and are not descriptions indicating limitations. In addition, the OFG 71 may be omitted from the pixel 50.

### Fifth Embodiment

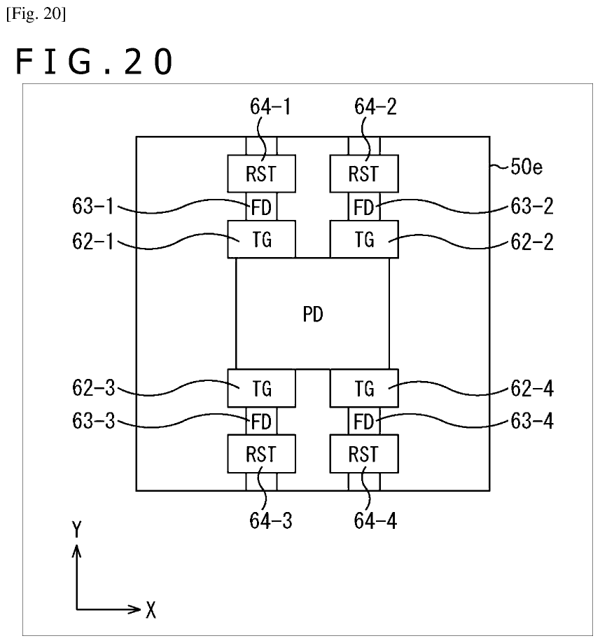

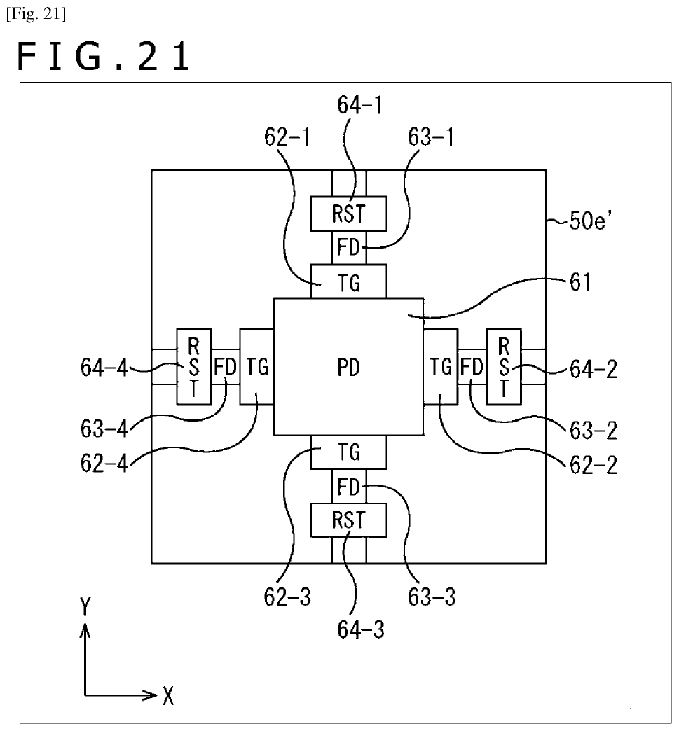

In the first to fourth embodiments, the 2 tap configuration has been described by way of example. The present technology is also applicable to the pixel 50 with the 4 tap configuration described with reference to FIG. 6. FIG. 20 and FIG. 21 illustrate configuration examples of the pixel 50 with the 4 tap configuration. Note that FIG. 20 and FIG. 21 do not illustrate a transistor such as the amplifying transistor 65 or the select transistor 66, but that the transistor is provided in each tap (each FD 63).

The pixel 50e depicted in FIG. 20 includes four sets each including the TG 62, the FD 63, and the RST 64 provided on an upper side and a lower side of the PD 61 in the figure. The upper side of the PD 61 is provided with the TG 62-1, the FD 63-1, and the RST 64-1 included in one tap. Additionally, the upper side of the PD 61 is provided with the TG 62-2, the FD 63-2, and the RST 64-2 included in one tap.

In addition, the lower side of the PD 61 is provided with a TG 62-3, an FD 63-3, and an RST 64-3 included in one tap. Additionally, the lower side of the PD 61 is provided with a TG 62-4, an FD 63-4, and an RST 64-4 included in one tap.

Each of the FDs 63-1 to 63-4 is provided at a position between the TG 62 and the RST 64 provided at respective positions parallel to the FD. Accordingly, as is the case with the first to fourth embodiments, the FDs 63-1 to 63-4 have an identical area.

As depicted in FIG. 21, the tap may be provided on each of the four sides of the PD 61. A pixel 50e′ depicted in FIG. 21 includes a set of the TG 62, the FD 63, and the RST 64 provided on each of the upper side, lower side, left side, and right side of the PD 61 in the figure.

The upper side of the PD 61 is provided with the TG 62-1, the FD 63-1, and the RST 64-1 included in one tap. Additionally, the right side of the PD 61 is provided with the TG 62-2, the FD 63-2, and the RST 64-2 included in one tap.

In addition, the lower side of the PD 61 is provided with the TG 62-3, the FD 63-3, and the RST 64-3 included in one tap. Additionally, the left side of the PD 61 is provided with the TG 62-4, the FD 63-4, and the RST 64-4 included in one tap.

Each of the FDs 63-1 to 63-4 is provided at a position between the TG 62 and the RST 64 provided at respective positions parallel to the FD. Accordingly, as is the case with the first to fourth embodiments, the FDs 63-1 to 63-4 have an identical area according to the fifth embodiment.

Note that, in the example described with reference to FIG. 20 and FIG. 21, the RST 64 is paired with the TG 62, with the FD 63 provided between the RST 64 and the TG 62, by way of example, but that this configuration may be combined with the pixel 50b according to the second embodiment to include the dummy gate 231 disposed in the pixel instead of the RST 64. Additionally, this configuration may be combined with the pixel 50c according to the third embodiment to include the FDG 251 disposed in the pixel instead of the RST 64.

### Sixth Embodiment

In the first to fifth embodiments, the TG 62 and the gate different from the TG 62 are configured parallel to each other, with the FD 63 formed between the TG 62 and the gate, by way of example. Instead of another gate paired with the TG 62, an element isolation portion can be used.

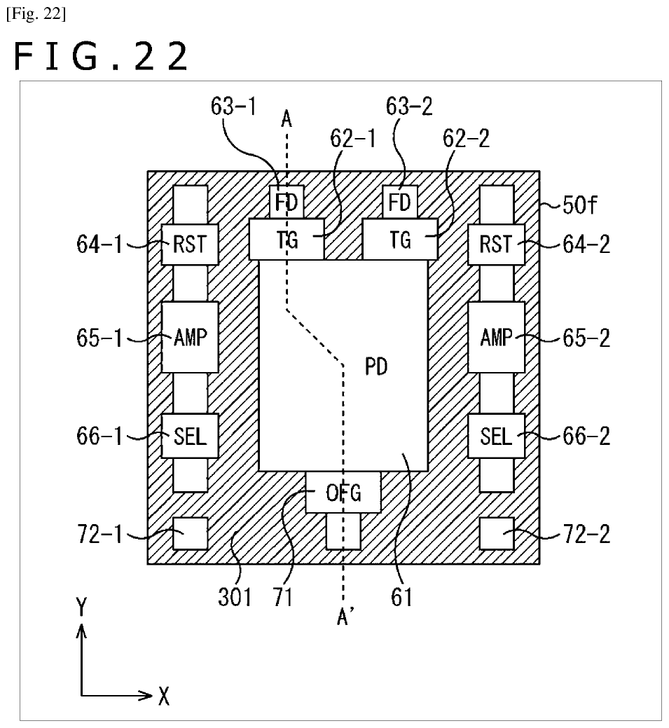

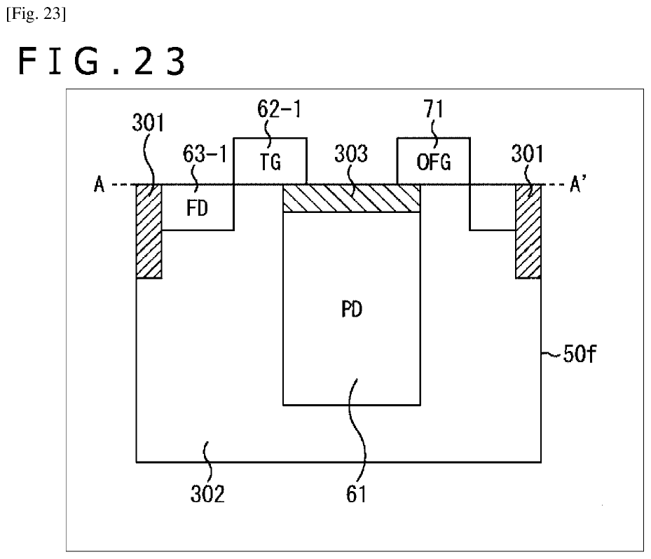

FIG. 22 is a plan view depicting a configuration example of a pixel 50f according to a sixth embodiment. FIG. 23 is a cross-sectional view depicting a cross-sectional configuration of the pixel 50f depicted in FIG. 22, the cross-sectional view being taken along segment A-A′ in the plan view.

An element isolation portion 301 is provided on the space of the pixel 50f. The element isolation portion 301 includes an insulator including an oxide film such as SiO2.

As depicted in FIG. 23, the PD 61 is provided in a Pwell 302 including an Si substrate. More specifically, the PD 61 includes an N-type impurity layer (charge storage layer) and a P-type impurity layer 303 that is additionally provided above the N-type impurity layer, includes a depletion prevention layer (pinning layer), and has a high concentration.

The FD 63-1, in which charge generated in the PD 61 is stored, is provided on the left side of the P type impurity layer 303 in the figure. In FIG. 23, the transfer gate (TG) 62-1 is provided across the P-type impurity layer 303 and the FD 63-1 in the lateral direction in the figure. When controllably turned on, the TG 62-1 transfers the charge stored in the PD 61 via the P-type impurity layer 303 to the FD 63-1 including the high-concentration N-type impurity layer.

On the other hand, the element isolation portion 301 (sometimes also referred to as STI (Shallow Trench Isolation) or the like) is provided on a left portion and a right portion of the Pwell 302 in the figure. The element isolation portion 301 is formed by forming a shallow trench and backfilling the trench with an insulator including an oxide film such as SiO2. The element isolation portion 301 can be configured using a diffusion layer with a conductivity type opposite to the conductivity type of a source and a drain of the transistor. For example, in a case where the source and the drain of the transfer transistor 62 are configured using an N type diffusion layer, the element isolation portion 301 can be configured using a P type diffusion layer.

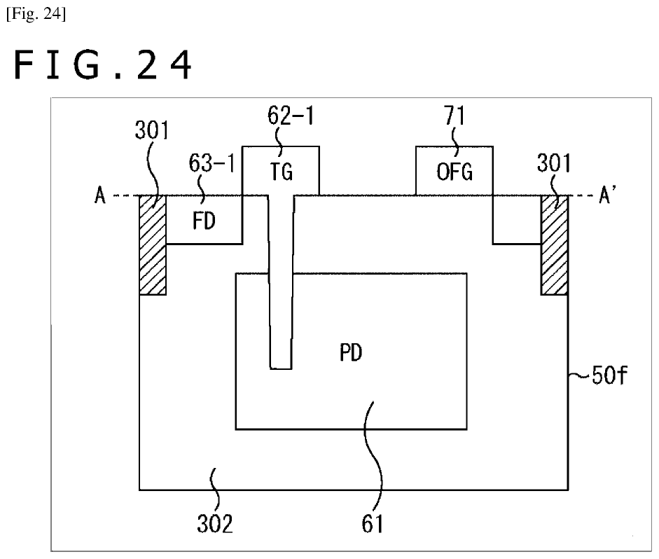

As depicted in FIG. 24, the TG 62-1 may be formed using a vertical transistor. A vertical transistor trench is formed in the TG 62-1 depicted in FIG. 24, and a transfer gate is formed at the vertical transistor trench to read out charge from the PD 61. The TG 62-1 thus configured as a vertical transistor enables charge to be efficiently read out even from a deep portion of the PD 61.

Note that the cross-sectional configuration depicted in FIG. 23 and FIG. 24 is also applicable to the pixels according to the above-described first to fifth embodiments. Furthermore, vertical transistors can also be used as the transistors other than the TG 62 (transfer transistor 62).

In the configuration of the pixel 50f depicted in FIGS. 22 to 24, the FD 63-1 is provided between the TG 62-1 and the element isolation portion 301, and the FD 63-2 is provided between the TG 62-2 and the element isolation portion 301. The element isolation portion 301 replaces, for example, the RST 64 in the pixel 50a according to the first embodiment. Specifically, the element isolation portion 301 is provided such that a distance between the TG 62-1 and the element isolation portion 301 is identical to a distance between the TG 62-2 and the element isolation portion 301, and thus the TG 62-1 and the TG 62-2 have an identical area in size.

Accordingly, in the pixel 50f, a plurality of the FDs 63 can be formed with no difference in area among the plurality of FDs 63.

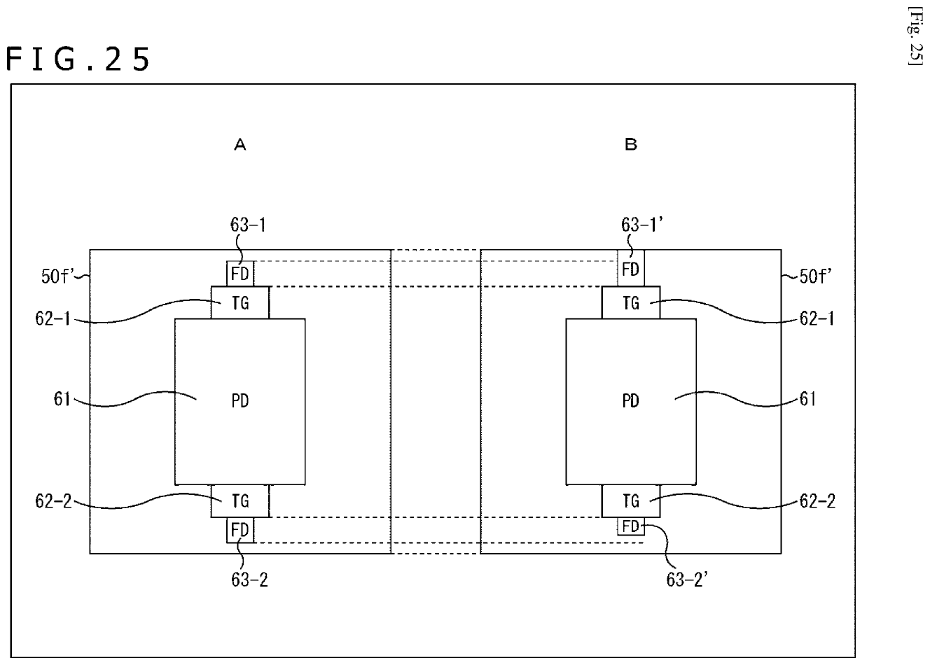

Note that a pixel 50f′ depicted in FIG. 25 may involve a difference in area among the plurality of FDs 63. The pixel 50f′ depicted in FIG. 25 illustrates a case where the TG 62-1 and the FD 63-1 are provided on the upper side of the PD 61 in the figure and where the TG 62-2 and the FD 63-2 are provided on the lower side of the PD 61 in the figure.

In a case where no displacement occurs between a mask used to form the element isolation portion 301 and a mask used to form the gate as depicted at A in FIG. 25, the FD 63-1 and the FD 63-2 formed can have an identical area. However, in a case where displacement occurs between the mask used to form the element isolation portion 301 and the mask used to form the gate as depicted at B in FIG. 25, specifically in a case where the mask is displaced in a different direction, an FD 63-1′ and an FD 63-2′ formed may have different areas.

The state illustrated at B in FIG. 25 indicates that, for example, the mask used to form the element isolation portion 301 is displaced upward in the figure, leading to the FD 63-1′ formed being larger than the FD 63-2′ formed. In a case where the element isolation portion 301 and the TG 62 are formed parallel to each other, with the FD 63 formed between the element isolation portion 301 and the TG 62, a difference in area may occur among the plurality of FDs 63 formed in the configuration in which the TG 62 and the FD 63 are formed on two different sides of the PD 61 as depicted in FIG. 25. Thus, as depicted in FIG. 22, a configuration is more preferable in which the TG 62 and the FD 63 are formed on an identical side of the PD 61.

Note that a pixel 50g′ configured as depicted in FIG. 25 is susceptible to displacement of the mask in the up-down direction as described above but is unsusceptible to displacement of the mask in the lateral direction. Specifically, in a case where a plurality of FDs 63 is formed in the up-down direction of the PD 61 as is the case with the pixel 50g′, a plurality of the FDs 63 can be formed with no difference in area among the FDs 63 even in a case where the mask is displaced during manufacture in the lateral direction, which is different from the up-down direction.

Accordingly, in a case where, for example, a manufacturing process allows possible displacement to be limited to the lateral direction, even the pixel 50g′ depicted in FIG. 25 can be formed with no difference in area among a plurality of the FDs 63, and the present technology can be applied to the pixel 50g′.

The sixth embodiment has been described taking the 2 tap case as an example, but is applicable to the 4 tap case.

### Seventh Embodiment

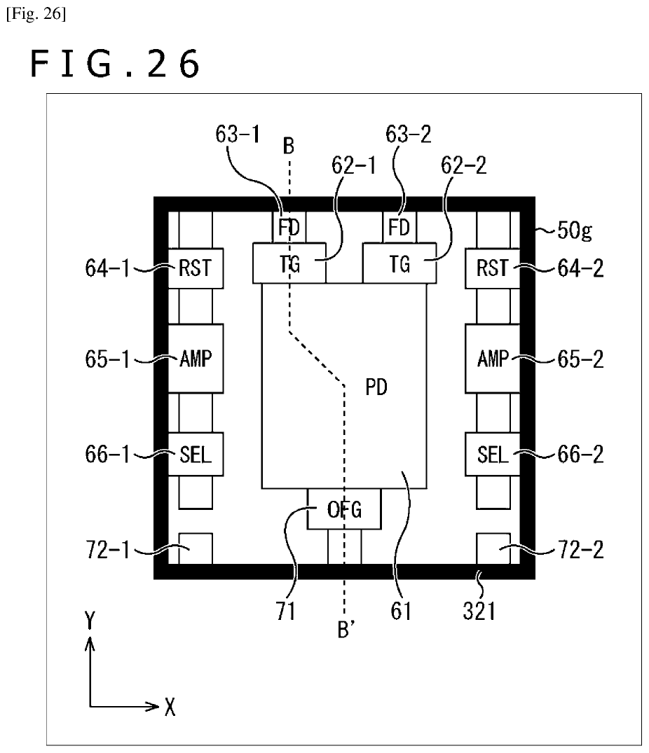

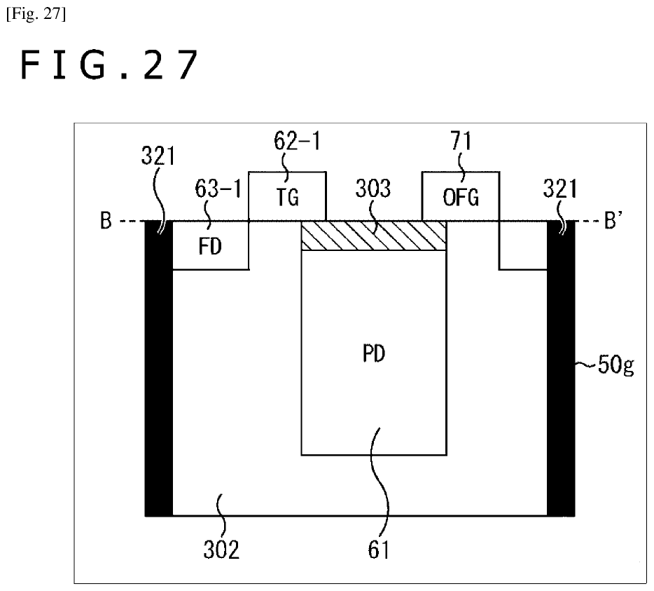

FIG. 26 is a plan view depicting a configuration example of the pixel 50g according to the seventh embodiment. FIG. 27 is a cross-sectional view depicting a cross-sectional configuration of the pixel 50g depicted in FIG. 26, the cross-sectional view being taken along segment B-B′ in the plan view.

An pixel separation portion 321 is provided in the pixel 50g. The pixel separation portion 321 is provided to surround one pixel 50g. The pixel separation portion 302 includes, for example, a trench that includes a sidewall film formed on an inner wall of the trench and that including SiO₂, the trench being filled with a filler including polysilicon.

The trench may be provided to penetrate the pixel 50g or to extend halfway through the pixel 50g. The pixel 50g depicted in FIG. 27 represents the case of penetration into the pixel 50g.

Note that SiO2 or SiN can be used as the sidewall film of the pixel separation portion 302. Additionally, polysilicon or doping polysilicon can be used as the filler. In addition, the interior of the trench in the pixel separation portion 302 may be filled with a material with a light shielding property, for example, metal such as tungsten or copper.

In this way, in a case where the pixel separation portion 321 is provided, the FD 63-1 is provided between the TG 62-1 and the pixel separation portion 321, and the FD 63-2 is provided between the TG 62-2 and the pixel separation portion 321.

The pixel separation portion 321 replaces, for example, the element isolation portion 301 in the pixel 50f according to the sixth embodiment. Specifically, the pixel separation portion 321 is provided such that a distance between the TG 62-1 and the pixel separation portion 321 is identical to a distance between the TG 62-2 and the pixel separation portion 321, and thus the TG 62-1 and the TG 62-2 that have an identical area in size can be formed.

The element isolation portion 301 and the pixel separation portion 321 are similar in that the trench is formed and filled with the predetermined material. Formation of the trench enables separation at that portion. In a case where such a separation portion is provided at the position paired with the TG 62, the plurality of FDs 63 can be made equal to one another in size as described above.

Accordingly, in the pixel 50g, the plurality of FDs 63 can be formed with no difference in area among the plurality of FDs 63.

Note that, in a case where, in the pixel 50g, the TG 62 and the FD 63 are formed on two different sides of the PD 61, as in the pixel 50f′ (FIG. 25), a difference in area may occur among the plurality of FDs 63 provided, and thus that a configuration is more preferable in which the TG 62 and the FD 63 are formed on an identical side of the PD 61 as depicted in FIG. 26.

The seventh embodiment has been described taking the 2 tap case as an example, but is applicable to the 4 tap case.

In this way, according to the present technology, in the pixel with the plurality of FDs, the plurality of FDs can be made identical in area, leading to the same conversion efficiency.

The pixels 50 according to the first to seventh embodiments can be used as pixels disposed in the pixel array section 41 (FIG. 2). Additionally, the pixel array section 41 can be used for an apparatus performing distance measurement as the distance measuring apparatus 10 (FIG. 1).

<Application to Endoscopic Surgery System>

The technology according to the present disclosure (present technology) can be applied to various products. For example, the technology according to the present disclosure may be applied to an endoscopic surgery system.

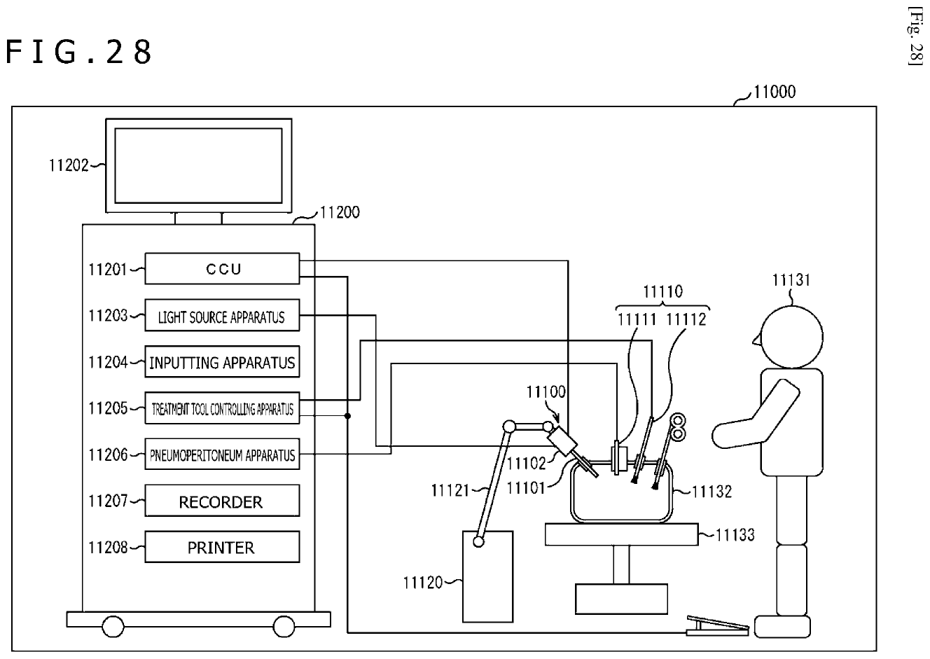

FIG. 28 is a view depicting an example of a schematic configuration of an endoscopic surgery system to which the technology according to an embodiment of the present disclosure (present technology) can be applied.

In FIG. 28, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

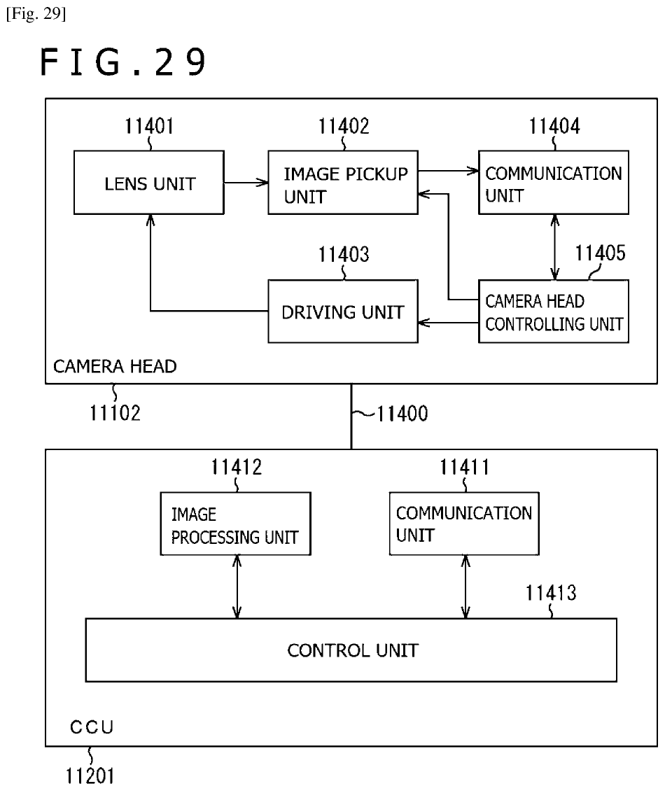

FIG. 29 is a block diagram depicting an example of a functional configuration of the camera head 11102 and the CCU 11201 depicted in FIG. 28.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

<Application to Mobile Body>

The technology according to the present disclosure (present technology) can be applied to various products. For example, the technology according to the present technology may be implemented as an apparatus mounted in any of various types of mobile bodies such as an automobile, an electric vehicle, a hybrid electric vehicle, a motorcycle, a bicycle, a personal mobility vehicle, an airplane, a drone, a ship, and a robot.

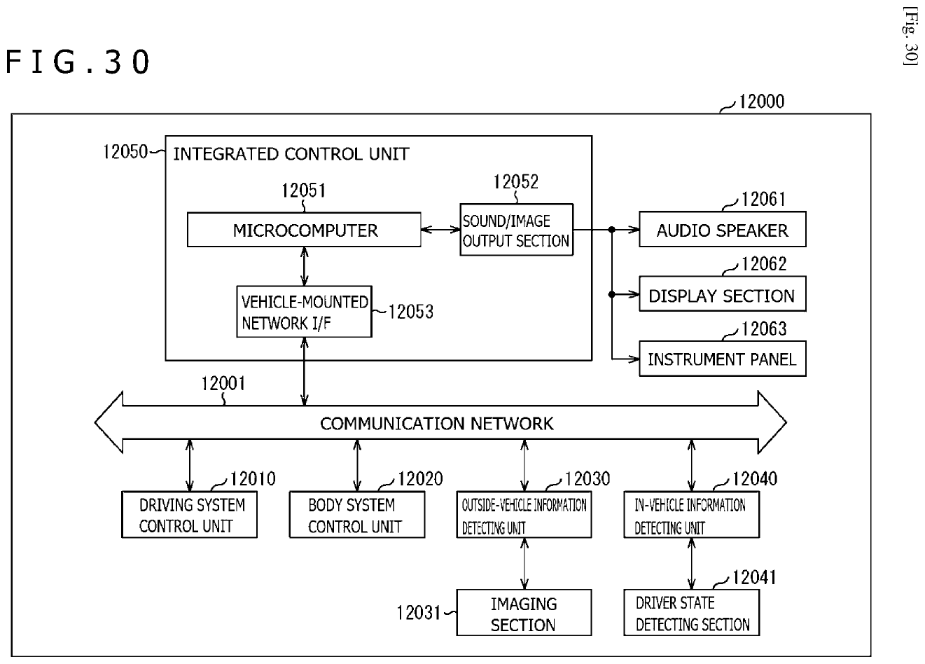

FIG. 30 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 30, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 30, an audio speaker 12061, a display section 12062, and an instrument panel 12063 are illustrated as the output device. The display section 12062 may, for example, include at least one of an on-board display and a head-up display.

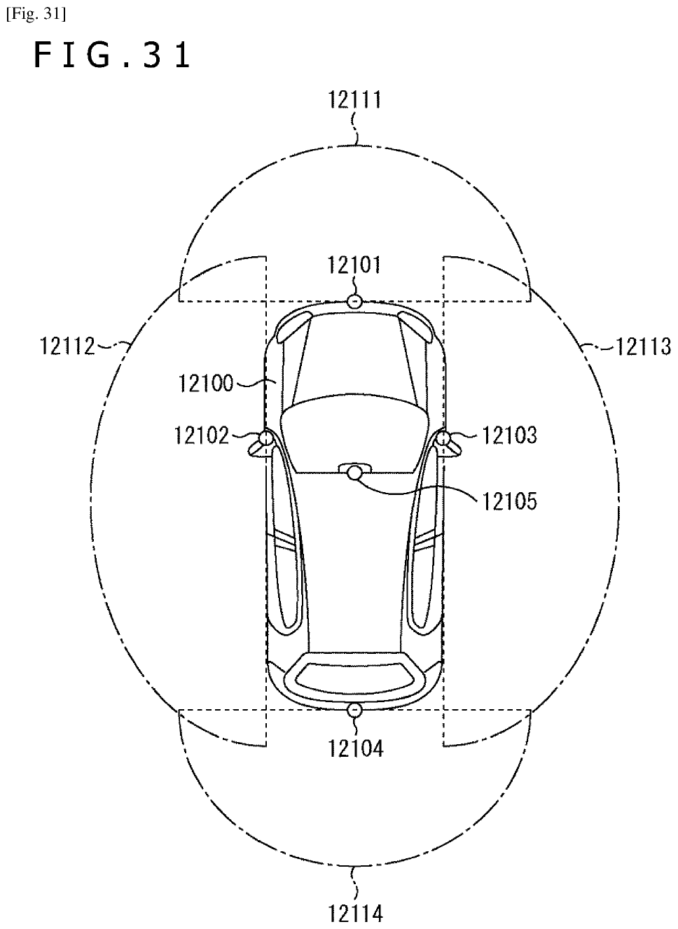

FIG. 31 is a diagram depicting an example of the installation position of the imaging section 12031.

In FIG. 31, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 31 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the specification, the system represents the whole apparatus including a plurality of apparatuses.

Note that the effects described in the specification are illustrative and are not restrictive, and that other effects may be produced.

Note that the embodiments of the present technology are not limited to the above-described embodiments, and that various changes can be made to the embodiments without departing from the spirits of the present technology.

Note that the present technology can also have the following configurations.

(1)

An imaging element including:

a photoelectric converting section configured to perform photoelectric conversion;

a plurality of charge storage sections configured to store charge obtained by the photoelectric converting section; and

a plurality of transfer sections configured to transfer the charge from the photoelectric converting section to each of the plurality of charge storage sections, in which each of the charge storage sections is provided between a first gate of a transistor included in a corresponding one of the transfer sections and a second gate provided at a position parallel to the first gate.

(2)

The imaging element according to (1) described above, in which

the second gate includes a gate of a reset transistor configured to reset the charge storage section.

(3)

The imaging element according to (1) described above, in which

the second gate includes a dummy gate.

(4)

The imaging element according to (1) described above, further including:

an additional capacitance section configured to add a capacitance to the charge storage section; and

an additional transistor configured to add the additional capacitance section to the charge storage section, in which

the charge storage section is provided between the first gate and the second gate included in the additional transistor.

(5)

The imaging element according to (4) described above, in which

the additional capacitance section is provided between the second gate and a third gate provided in an adjacent pixel.

(6)

An imaging element including:

a photoelectric converting section configured to perform photoelectric conversion;

a plurality of charge storage sections configured to store charge obtained by the photoelectric converting section;

a plurality of transfer sections configured to transfer the charge from the photoelectric converting section to each of the plurality of charge storage sections; and

a trench provided parallel to a gate of a transistor included in a corresponding one of the transfer sections, in which

each of the charge storage sections is provided between the gate and the trench.

(7)

The imaging element according to (6) described above, in which

the trench is provided to surround a pixel.

(8)

The imaging element according to any one of (1) to (7) described above, in which two or four of the charge storage sections are provided in the pixel.

(9)

The imaging element according to any one of (1) to (8), in which

the plurality of charge storage sections is disposed in a line symmetric or point symmetric relationship with the plurality of transfer sections.

(10)

A distance measuring apparatus including:

a light emitting section configured to emit irradiation light;

a light receiving section configured to receive reflected light resulting from reflection of the irradiation light at a target object; and

a computation section configured to compute a distance to the target object on the basis of a period of time from emission of the irradiation light until reception of the reflected light, in which

an imaging element disposed in the light receiving section includes

a photoelectric converting section configured to perform photoelectric conversion,

a plurality of charge storage sections configured to store charge obtained by the photoelectric converting section, and

a plurality of transfer sections configured to transfer the charge from the photoelectric converting section to each of the plurality of charge storage sections, and

each of the charge storage sections is provided between a first gate of a transistor included in a corresponding one of the transfer sections and a second gate provided at a position parallel to the first gate.

### REFERENCE SIGNS LIST

10 Distance measuring apparatus
11 Lens
12 Light receiving section
13 Signal processing section
14 Light emitting section
15 Light emission control section
21 Pattern switching section
22 Distance image generating section
23 Column processing section
31 Photodiode
41 Pixel array section
42 Vertical driving section
43 Column processing section
44 Horizontal driving section
45 System control section
46 Pixel driving line
47 Vertical signal line
48 Signal processing section
50 Pixel
51 Tap
61 Photodiode
62 Transfer transistor
63 FD, 64 Reset transistor
65 Amplifying transistor
66 Select transistor
71 Discharge transistor
72 Well contact, 121 Mask
131 Opening, 231 Dummy gate
251 Transistor for conversion efficiency switching
252 Additional capacitance
301 Element isolation portion
302 Pixel separation portion
303 P-type impurity layer
321 Pixel separation portion

What is claimed is:

1. An imaging element, comprising:
a photoelectric converting section configured to perform photoelectric conversion;
a plurality of charge storage sections configured to store charge obtained by the photoelectric converting section; and
a plurality of transfer sections configured to transfer the charge from the photoelectric converting section to each of the plurality of charge storage sections, wherein
each of the charge storage sections is provided between a first gate of a transistor included in a corresponding one of the transfer sections and a second gate provided at a position parallel to the first gate.

2. The imaging element according to claim 1, wherein
the second gate includes a gate of a reset transistor configured to reset the charge storage section.

3. The imaging element according to claim 1, wherein
the second gate includes a dummy gate.

4. The imaging element according to claim 1, further comprising:
an additional capacitance section configured to add a capacitance to the charge storage section; and
an additional transistor configured to add the additional capacitance section to the charge storage section, wherein
the charge storage section is provided between the first gate and the second gate included in the additional transistor.

5. The imaging element according to claim 4, wherein
the additional capacitance section is provided between the second gate and a third gate provided in an adjacent pixel.

6. An imaging element, comprising:
a photoelectric converting section configured to perform photoelectric conversion;
a plurality of charge storage sections configured to store charge obtained by the photoelectric converting section;
a plurality of transfer sections configured to transfer the charge from the photoelectric converting section to each of the plurality of charge storage sections; and
a trench provided parallel to a gate of a transistor included in a corresponding one of the transfer sections, wherein
each of the charge storage sections is provided between the gate and the trench.

7. The imaging element according to claim 6, wherein
the trench is provided to surround a pixel.

8. The imaging element according to claim 1, wherein
two or four of the charge storage sections are provided in a pixel.

9. The imaging element according to claim 1, wherein
the plurality of charge storage sections is disposed in a line symmetric or point symmetric relationship with the plurality of transfer sections.

10. A distance measuring apparatus, comprising:
a light emitting section configured to emit irradiation light;
a light receiving section configured to receive reflected light resulting from reflection of the irradiation light at a target object; and
a computation section configured to compute a distance to the target object on a basis of a period of time from emission of the irradiation light until reception of the reflected light, wherein
an imaging element disposed in the light receiving section includes
a photoelectric converting section configured to perform photoelectric conversion,
a plurality of charge storage sections configured to store charge obtained by the photoelectric converting section, and
a plurality of transfer sections configured to transfer the charge from the photoelectric converting section to each of the plurality of charge storage sections, and
each of the charge storage sections is provided between a first gate of a transistor included in a corresponding one of the transfer sections and a second gate provided at a position parallel to the first gate.
